(19) United States
(12) Patent Application Publication
(10) Pub. No.: US 2025/0318345 A1
(43) Pub. Date: Oct. 9, 2025

(54) DISPLAY DEVICE

(71) Applicant: Samsung Display Co., LTD., Yongin-si (KR)

(72) Inventors: Jong Moo HUH, Yongin-si (KR); Jae Phil LEE, Yongin-si (KR)

(21) Appl. No.: 18/965,890

(22) Filed: Dec. 2, 2024

(30) Foreign Application Priority Data
Apr. 9, 2024 (KR) 10-2024-0048286

(51) Int. Cl. H10K 59/90

(52) U.S. Cl. CPC H10H 29/49; H10H 29/24; H10K 59/90

(57) ABSTRACT

A display device includes a first subpixel in a display area. The first subpixel includes a first pixel electrode on a substrate, a first light emitting element of a first color on the first pixel electrode and including a first inorganic light emitting layer configured to emit light of the first color, and a second light emitting element of the first color on the first light emitting element of the first color and including a first organic light emitting layer configured to emit light of the first color.

### CROSS-REFERENCE TO RELATED APPLICATION

This application claims priority to and the benefit of Korean Patent Application No. 10-2024-0048286, filed on Apr. 9, 2024, in the Korean Intellectual Property Office, the entire disclosure of which is incorporated by reference herein.

### BACKGROUND

### 1. Field

Embodiments of the present disclosure relate to a display device.

### 2. Description of the Related Art

As the information society develops, demands for display devices for displaying images are increasing in various forms. Accordingly, various types of display devices including light emitting display devices are being developed.

### SUMMARY

Aspects and features of embodiments of the present disclosure provide a display device which can reduce power consumption.

However, aspects and features of embodiments of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, there is provided a display device including a first subpixel in a display area. The first subpixel may include a first pixel electrode on a substrate, a first light emitting element of a first color on the first pixel electrode and including a first inorganic light emitting layer configured to emit light of the first color, and a second light emitting element of the first color on the first light emitting element of the first color and including a first organic light emitting layer configured to emit light of the first color.

In one or more embodiments, the first subpixel may further include a transparent electrode on the first light emitting element of the first color and connecting the first light emitting element of the first color and the second light emitting element of the first color.

In one or more embodiments, the transparent electrode may have a larger size than the first light emitting element of the first color in a plan view and may completely cover an upper surface of the first light emitting element of the first color.

In one or more embodiments, the display device may further include a light blocking layer around an emission area where the first pixel electrode, the first light emitting element of the first color and the second light emitting element of the first color are located. The first organic light emitting layer may be on the transparent electrode and may fill the emission area.

In one or more embodiments, the display device may further include a common electrode on the first organic light emitting layer. The first light emitting element of the first color and the second light emitting element of the first color may be connected in series between the first pixel electrode and the common electrode.

In one or more embodiments, the first light emitting element of the first color may include a textured pattern at (e.g., formed on) an upper surface of the first light emitting element of the first color.

In one or more embodiments, the transparent electrode on the first light emitting element may include an optical pattern having a shape corresponding to the textured pattern.

In one or more embodiments, the first light emitting element of the first color may be a micro-light emitting diode.

In one or more embodiments, the display device may further include a first color filter on the first light emitting element of the first color and the second light emitting element of the first color and configured to selectively transmit light of the first color.

In one or more embodiments, the display device may further include a second subpixel in the display area. The second subpixel may include a second pixel electrode on the substrate, a first light emitting element of a second color on the second pixel electrode and including a second inorganic light emitting layer configured to emit light of the second color, and a second light emitting element of the second color on the first light emitting element of the second color and including a second organic light emitting layer configured to emit light of the second color.

In one or more embodiments, the display device may further include a common electrode on the second organic light emitting layer. The first light emitting element of the second color and the second light emitting element of the second color may be connected in series between the second pixel electrode and the common electrode.

In one or more embodiments, the display device may further include a second color filter on the first light emitting element of the second color and the second light emitting element of the second color and configured to selectively transmit light of the second color.

In one or more embodiments, the display device may further include a third subpixel in the display area. The third subpixel may include a third pixel electrode on the substrate, a first light emitting element of a third color on the third pixel electrode and including a third inorganic light emitting layer configured to emit light of the third color, and a second light emitting element of the third color on the first light emitting element of the third color and including a third organic light emitting layer configured to emit light of the third color.

In one or more embodiments, the display device may further include a common electrode on the third organic light emitting layer. The first light emitting element of the third color and the second light emitting element of the third color may be connected in series between the third pixel electrode and the common electrode.

In one or more embodiments, the display device may further include a third color filter on the first light emitting element of the third color and the second light emitting element of the third color and configured to selectively transmit light of the third color.

In one or more embodiments, the light of the first color may be red light, the light of the second color may be green light, and the light of the third color may be blue light.

According to one or more embodiments of the present disclosure, there is provided a display device including a pixel in a display area. The pixel may include a first subpixel including a first pixel electrode, a first light emitting element of a first color on the first pixel electrode, and a second light emitting element of the first color on the first light emitting element of the first color, a second subpixel including a second pixel electrode, a first light emitting element of a second color on the second pixel electrode, and a second light emitting element of the second color on the first light emitting element of the second color, and a third subpixel including a third pixel electrode, a first light emitting element of a third color on the third pixel electrode, and a second light emitting element of the third color on the first light emitting element of the third color.

In one or more embodiments, each of the first light emitting element of the first color, the first light emitting element of the second color, and the first light emitting element of the third color may include an inorganic light emitting layer.

In one or more embodiments, each of the second light emitting element of the first color, the second light emitting element of the second color, and the second light emitting element of the third color may include an organic light emitting layer.

In one or more embodiments, the display device may further include a first color filter on the first light emitting element of the first color and the second light emitting element of the first color and configured to selectively transmit light of the first color, a second color filter on the first light emitting element of the second color and the second light emitting element of the second color and configured to selectively transmit light of the second color, and a third color filter on the first light emitting element of the third color and the second light emitting element of the third color and configured to selectively transmit light of the third color.

According to one or more embodiments of the present disclosure, there is provided an electronic device for providing an image, including a display device, the display device including a first subpixel in a display area. The first subpixel may include a first pixel electrode on a substrate, a first light emitting element of a first color on the first pixel electrode and including a first inorganic light emitting layer configured to emit light of the first color, and a second light emitting element of the first color on the first light emitting element of the first color and including a first organic light emitting layer configured to emit light of the first color.

A display device according to one or more embodiments includes a subpixel including a first light emitting element and a second light emitting element. In one or more embodiments, the first light emitting element and the second light emitting element may include an inorganic light emitting layer and an organic light emitting layer, respectively, and may be connected to each other in series between a pixel electrode and a common electrode. According to one or more embodiments, a utilization rate of a driving current supplied to the subpixel can be increased, and the power consumption of the display device can be reduced.

However, effects, aspects, and features according to one or more embodiments of the present disclosure are not limited to those exemplified above and various other effects, aspects, and features are incorporated herein.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to one or more embodiments;

FIG. 2 is a layout view of a display device according to one or more embodiments;

FIG. 3 is a block diagram of a display device according to one or more embodiments;

FIG. 4 is an equivalent circuit diagram of a subpixel according to one or more embodiments;

FIG. 5 is a layout view illustrating pixels of a display area according to one or more embodiments;

FIG. 6 is a cross-sectional view illustrating an example of a cross section of a display panel corresponding to the line I1-I1′ of FIG. 5;

FIG. 7 is a detailed cross-sectional view of an example of an area A of FIG. 6;

FIG. 8 is an equivalent circuit diagram of a subpixel according to one or more embodiments;

FIG. 9 is a layout view illustrating pixels of a display area according to one or more embodiments;

FIG. 10 is a layout view illustrating pixels of a display area according to one or more embodiments;

FIG. 11 is a cross-sectional view illustrating an example of a cross section of a display panel corresponding to the line I2-I2′ of FIG. 10;

FIG. 12 is a detailed cross-sectional view of an example of an area B of FIG. 11;

FIG. 13 is a cross-sectional view illustrating an example of a cross section of a display panel corresponding to the line I2-I2′ of FIG. 10;

FIG. 14 is an example view of a virtual reality (VR) device including a display device according to one or more embodiments;

FIG. 15 is an example view of a smart watch including a display device according to one or more embodiments;

FIG. 16 is an example view illustrating a vehicle instrument cluster and center fascia including display devices according to one or more embodiments; and

FIG. 17 is an example view of a transparent display device including a display device according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

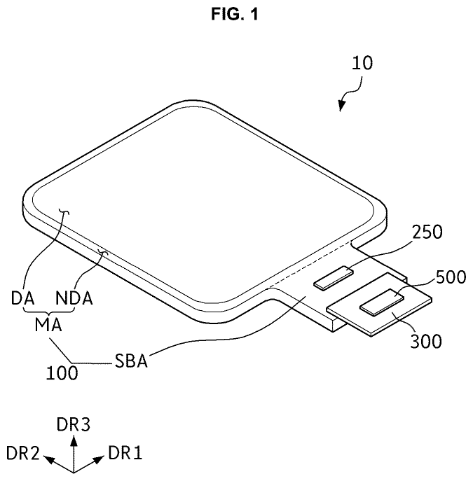

FIG. 1 is a perspective view of a display device 10 according to one or more embodiments.

Referring to FIG. 1, the display device 10 is a device for displaying moving images and/or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and/or Internet of things (IoT) devices.

The display device 10 may be a light emitting display device such as an organic light emitting display device using an organic light emitting diode (OLED), a quantum dot light emitting display device including a quantum dot light emitting layer, an inorganic light emitting display device including an inorganic semiconductor, or a micro- or nano-light emitting display device using a micro- or nano-light emitting diode. A case where the display device 10 is a micro- or nano-light emitting display device will be mainly described below, but the present disclosure is not limited thereto. For ease of description, a micro- or nano-light emitting diode will be referred to as a light emitting element.

The display device 10 includes a display panel 100, a display driving circuit 250, a circuit board 300, and a power supply unit 500.

The display panel 100 may be shaped like a rectangular plane having short sides in a first direction DR1 and long sides in a second direction DR2 intersecting the first direction DR1. Each corner where a short side extending in the first direction DR1 meets a long side extending in the second direction DR2 may be rounded to have a suitable curvature (e.g., a predetermined curvature) or may be right-angled. The planar shape of the display panel 100 is not limited to a quadrangular shape but may also be other polygonal shapes, a circular shape, and/or an elliptical shape. The display panel 100 may be formed flat, but the present disclosure is not limited thereto. For example, the display panel 100 may include a curved portion formed at left and right ends and having a constant or varying curvature. In addition, the display panel 100 may be formed to be flexible so that it can be curved, bent, folded, and/or rolled.

The display panel 100 may include a main area MA and a sub-area SBA.

The main area MA may include a display area DA that displays an image and a non-display area NDA disposed around the display area DA along an edge or a periphery of the display area DA. The display area DA may include a plurality of pixels that display an image. Each of the pixels may include a plurality of subpixels. For example, each of the pixels may include a first subpixel that emits light of a first color, a second subpixel that emits light of a second color, and a third subpixel that emits light of a third color, but the present disclosure is not limited thereto.

The sub-area SBA may protrude from a side of the main area MA in the second direction DR2. Although the sub-area SBA is unfolded in FIG. 1, it may be bent. In this case, the sub-area SBA may be placed on a lower surface of the display panel 100. When the sub-area SBA is bent, it may be overlapped by the main area MA in a third direction DR3 which is a thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached onto the display panel 100 using a chip on glass (COG) method, a chip on plastic (COP) method, and/or an ultrasonic bonding method. However, the present disclosure is not limited thereto. For example, the display driving circuit 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a printed circuit board (PCB), or a flexible film such as a chip on film (COF).

The power supply unit 500 may generate a plurality of panel driving voltages according to a power supply voltage from the outside. The power supply unit 500 may be formed as an integrated circuit and attached onto the circuit board 300 using a COF method.

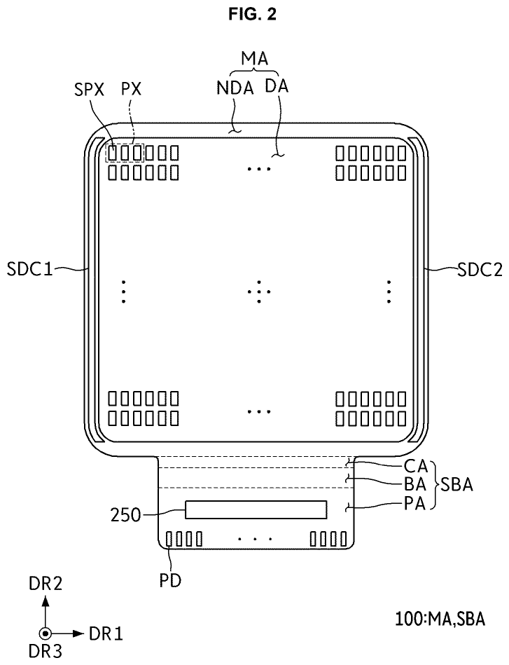

FIG. 2 is a layout view of the display device 10 according to one or more embodiments. FIG. 2 illustrates a state in which the sub-area SBA is unfolded.

Referring to FIG. 2, the display panel 100 may include the main area MA and the sub-area SBA.

The main area MA may include the display area DA that displays an image and the non-display area NDA disposed around the display area DA. The display area DA may occupy most of the main area MA. The display area DA may be disposed in the center of the main area MA.

The display area DA may include a plurality of pixels PX for displaying an image, and each of the pixels PX may include a plurality of subpixels SPX. A pixel PX may be defined as a smallest subpixel group that can express a white gray level.

The non-display area NDA may neighbor the display area DA. The non-display area NDA may be an area outside the display area DA. The non-display area NDA may be around (e.g., may surround) the display area DA. The non-display area NDA may be an edge area of the display panel 100.

A first scan driver SDC1 and a second scan driver SDC2 may be disposed in the non-display area NDA. The first scan driver SDC1 may be disposed on a side (e.g., a left side) of the display panel 100, and the second scan driver SDC2 may be disposed on the other side (e.g., a right side) of the display panel 100. However, the present disclosure is not limited thereto. Each of the first scan driver SDC1 and the second scan driver SDC2 may be electrically connected to the display driving circuit 250 through scan fan-out lines. Each of the first scan driver SDC1 and the second scan driver SDC2 may receive a scan control signal from the display driving circuit 250, generate scan signals according to the scan control signal, and output the scan signals to scan lines.

The sub-area SBA may protrude from a side of the main area MA in the second direction DR2. A length of the sub-area SBA in the second direction DR2 may be smaller than a length of the main area MA in the second direction DR2. A length of the sub-area SBA in the first direction DR1 may be smaller than a length of the main area MA in the first direction DR1 or may be substantially equal to the length of the main area MA in the first direction DR1. The sub-area SBA may be bent and placed under the display panel 100. In this case, the sub-area SBA may be overlapped by the main area MA in the third direction DR3.

The sub-area SBA may include a connection area CA, a pad area PA, and a bending area BA.

The connection area CA is an area protruding from a side of the main area MA in the second direction DR2. A side of the connection area CA may contact the non-display area NDA of the main area MA, and the other side of the connection area CA may contact the bending area BA.

The pad area PA is an area where pads PD and the display driving circuit 250 are disposed. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. A side of the pad area PA may contact the bending area BA.

The bending area BA is a bendable area. When the bending area BA is bent, the pad area PA may be placed under the connection area CA and the main area MA. The bending area BA may be disposed between the connection area CA and the pad area PA. A side of the bending area BA may contact the connection area CA, and the other side of the bending area BA may contact the pad area PA.

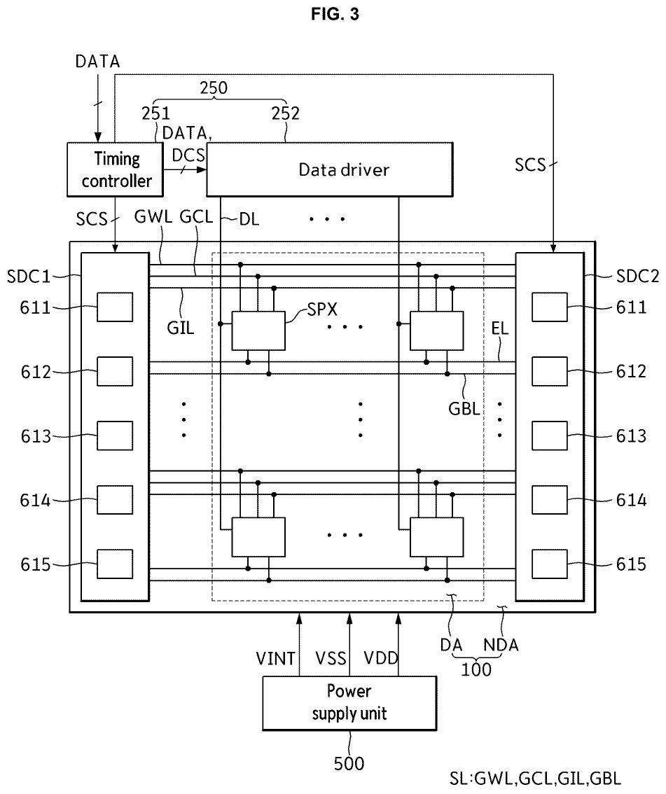

FIG. 3 is a block diagram of the display device 10 according to one or more embodiments.

Referring to FIG. 3, the display area DA includes a plurality of pixels PX, a plurality of scan lines SL, a plurality of emission control lines EL, and a plurality of data lines DL.

The pixels PX may be arranged in a matrix form along the first direction DR1 and the second direction DR2. For example, the pixels PX may be arranged along rows and columns of a matrix along the first direction DR1 and the second direction DR2. The scan lines SL and the emission control lines EL may extend in the first direction DR1 and may be arranged along the second direction DR2. The data lines DL may extend in the second direction DR2 and may be arranged along the first direction DR1. The scan lines SL include a plurality of write scan lines GWL, a plurality of control scan lines GCL, a plurality of initialization scan lines GIL, and a plurality of bias scan lines GBL.

Each of a plurality of subpixels SPX may be connected to one of the write scan lines GWL, one of the control scan lines GCL, one of the initialization scan lines GIL, one of the bias scan lines GBL, one of the emission control lines EL, and one of the data lines DL. Each of the subpixels SPX may receive a data voltage of a data line DL according to a write scan signal of a write scan line GWL and may emit light from a light emitting element according to the data voltage.

The non-display area NDA includes the first scan driver SDC1, the second scan driver SDC2, and the display driving circuit 250.

Each of the first scan driver SDC1 and the second scan driver SDC2 may include a write scan signal output unit 611, a control scan signal output unit 612, an initialization scan signal output unit 613, a bias scan signal output unit 614, and an emission signal output unit 615. Each of the write scan signal output unit 611, the control scan signal output unit 612, the initialization scan signal output unit 613, the bias scan signal output unit 614, and the emission signal output unit 615 may receive a scan timing control signal SCS from a timing controller 251. The write scan signal output unit 611 may generate write scan signals according to the scan timing control signal SCS of the timing controller 251 and sequentially output the write scan signals to the write scan lines GWL. The control scan signal output unit 612 may generate control scan signals according to the scan timing control signal SCS and sequentially output the control scan signals to the control scan lines GCL. In one or more embodiments, the write scan signals may also be used as the control scan signals. In this case, each of the first scan driver SDC1 and the second scan driver SDC2 may not include the control scan signal output unit 612. The initialization scan signal output unit 613 may generate initialization scan signals according to the scan timing control signal SCS and sequentially output the initialization scan signals to the initialization scan lines GIL. The bias scan signal output unit 614 may generate bias scan signals according to the scan timing control signal SCS and sequentially output the bias scan signals to the bias scan lines GBL. The emission signal output unit 615 may generate emission control signals according to the scan timing control signal SCS and sequentially output the emission control signals to the emission control lines EL.

The display driving circuit 250 includes the timing controller 251 and a data driver 252.

The data driver 252 may receive digital video data DATA and a data timing control signal DCS from the timing controller 251. The data driver 252 converts the digital video data DATA into analog data voltages according to the data timing control signal DCS and outputs the analog data voltages to the data lines DL. In this case, subpixels SPX may be selected by write scan signals of the first scan driver SDC1 and the second scan driver SDC2, and the data voltages may be supplied to the selected subpixels SPX.

The timing controller 251 may receive the digital video data DATA and timing signals from the outside. The timing controller 251 may generate the scan timing control signal SCS and the data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power supply voltage supplied from the outside. For example, the power supply unit 500 may generate a first driving voltage VDD, a second driving voltage VSS, and a third driving voltage VINT and supply them to the display panel 100.

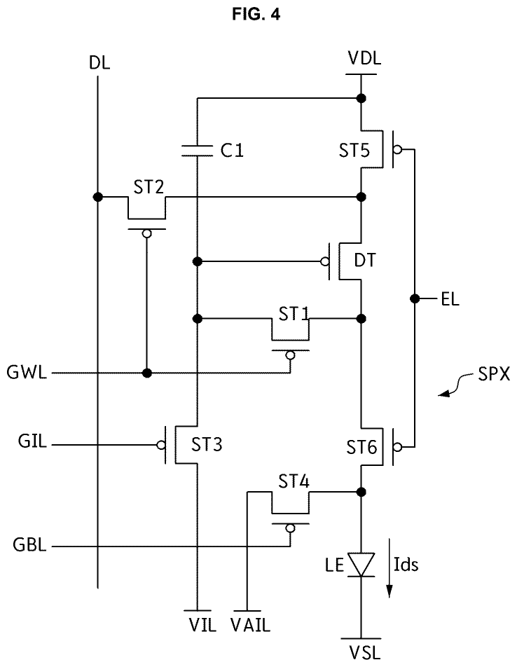

FIG. 4 is an equivalent circuit diagram of a subpixel SPX according to one or more embodiments.

Referring to FIG. 4, the subpixel SPX according to the embodiment may be connected to scan lines GWL, GIL and GBL, an emission control line EL, and a data line DL. For example, the subpixel SPX may be connected to a write scan line GWL, an initialization scan line GIL, a bias scan line GBL, the emission control line EL, and the data line DL. In one or more embodiments, when different scan signals are transmitted to a first transistor ST1 and a second transistor ST2, the subpixel SPX may be further connected to an additional scan line (e.g., a control scan line GCL of FIG. 3) connected to a gate electrode of the first transistor ST1.

The subpixel SPX according to the embodiment includes a driving transistor DT, switch elements, a capacitor C1, and a light emitting element LE. The switch elements include first through sixth transistors ST1 through ST6.

The driving transistor DT includes a gate electrode, a first electrode, and a second electrode. The driving transistor DT controls a drain-source current Ids (hereinafter, referred to as a “driving current”) flowing between the first electrode and the second electrode according to a data voltage applied to the gate electrode of the driving transistor DT.

The light emitting element LE may be a micro-light emitting diode.

The light emitting element LE emits light according to the driving current Ids. The amount of light emitted from the light emitting element LE may be proportional to the driving current Ids. An anode of the light emitting element LE may be connected to a first electrode of the fourth transistor ST4 and a second electrode of the sixth transistor ST6, and a cathode may be connected to a second power line VSL to which the second driving voltage VSS (see FIG. 3) is applied.

The capacitor C1 is formed between the gate electrode of the driving transistor DT and a first power line VDL to which the first driving voltage VDD (see FIG. 3) is applied. The first driving voltage VDD may be at a higher level than the second driving voltage VSS. One electrode of the capacitor C1 may be connected to the gate electrode of the driving transistor DT, and the other electrode may be connected to the first power line VDL.

As illustrated in FIG. 4, the first through sixth transistors ST1 through ST6 and the driving transistor DT may all be formed as p-type metal-oxide-semiconductor field effect transistors (MOSFETs). In this case, an active layer of each of the first through sixth transistors ST1 through ST6 and the driving transistor DT may be made of polysilicon.

The gate electrode of the first transistor ST1 and a gate electrode of the second transistor ST2 may be connected to the write scan line GWL, a gate electrode of the third transistor ST3 may be connected to the initialization scan line GIL, a gate electrode of the fourth transistor ST4 may be connected to the bias scan line GBL, and a gate electrode of the fifth transistor ST5 and a gate electrode of the sixth transistor ST6 may be connected to the emission control line EL. Because the first through sixth transistors ST1 through ST6 are formed as p-type MOSFETs, they may be turned on when a scan signal of a gate-low voltage and an emission control signal of a gate-low voltage are transmitted to the initialization scan line GIL, the write scan line GWL, the bias scan line GBL, and the emission control line EL. One electrode of the third transistor ST3 and one electrode of the fourth transistor ST4 may be connected to the same initialization voltage line or may be connected to different initialization voltage lines. In one or more embodiments, one electrode of the third transistor ST3 and one electrode of the fourth transistor ST4 may be connected to a first initialization voltage line VIL to which the third driving voltage VINT (see FIG. 3) is applied. Alternatively, one electrode of the third transistor ST3 may be connected to the first initialization voltage line VIL, and one electrode of the fourth transistor ST4 may be connected to a second initialization voltage line VAIL to which a fourth driving voltage (e.g., a second initialization voltage) is applied.

Alternatively, the driving transistor DT, the second transistor ST2, the fourth transistor ST4, the fifth transistor ST5, and the sixth transistor ST6 may be formed as p-type MOSFETs, and the first transistor ST1 and the third transistor ST3 may be formed as n-type MOSFETs. The active layer of each of the driving transistor DT, the second transistor ST2, the fourth transistor ST4, the fifth transistor ST5, and the sixth transistor ST6 formed as p-type MOSFETs may be made of polysilicon, and the active layer of each of the first transistor ST1 and the third transistor ST3 formed as n-type MOSFETs may be made of an oxide semiconductor.

In this case, because the first transistor ST1 and the third transistor ST3 are formed as n-type MOSFETs, the first transistor ST1 may be turned on in response to a write scan signal of a gate-high voltage or a control scan signal of a gate-high voltage transmitted to the control scan line GCL separated from the write scan line GWL), and the third transistor ST3 may be turned on in response to an initialization scan signal of a gate-high voltage. On the other hand, because the second transistor ST2, the fourth transistor ST4, the fifth transistor ST5, and the sixth transistor ST6 are formed as p-type MOSFETs, they may be turned on in response to a scan signal of a gate-low voltage and an emission control signal of a gate-low voltage.

Alternatively, the fourth transistor ST4 may be formed as an n-type MOSFET. Accordingly, the active layer of the fourth transistor ST4 may be made of an oxide semiconductor. When the fourth transistor ST4 is formed as an n-type MOSFET, it may be turned on in response to a bias scan signal of a gate-high voltage.

Alternatively, the first through sixth transistors ST1 through ST6 and the driving transistor DT may all be formed as n-type MOSFETs. In this case, the active layer of each of the first through sixth transistors ST1 through ST6 and the driving transistor DT may be made of an oxide semiconductor.

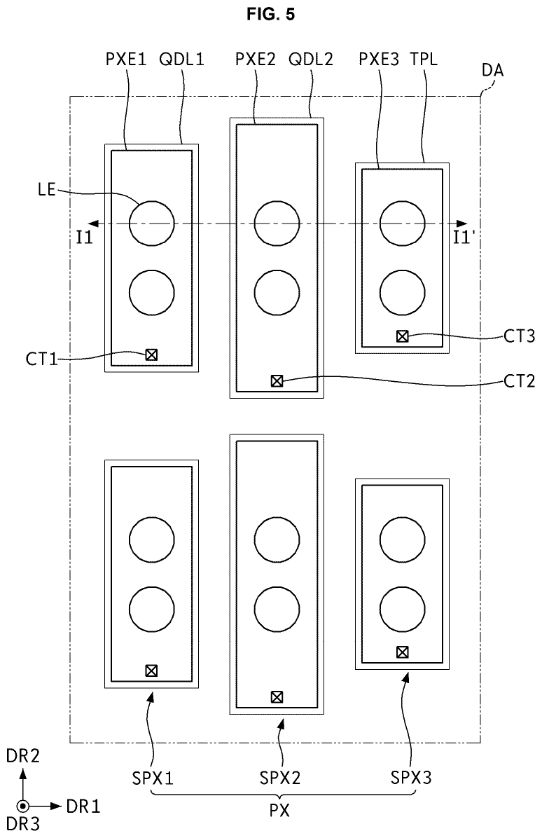

FIG. 5 is a layout view illustrating pixels PX of a display area DA according to one or more embodiments.

Referring to FIG. 5, each of the pixels PX in the display area DA may include three subpixels SPX1 through SPX3. However, the present disclosure is not limited thereto, and each of the pixels PX may also include four subpixels. When each of the pixels PX includes three subpixels SPX1 through SPX3, it may include a first subpixel SPX1, a second subpixel SPX2, and a third subpixel SPX3.

The pixels PX may be arranged in a matrix form. In each of the pixels PX, the first subpixel SPX1, the second subpixel SPX2, and the third subpixel SPX3 may be arranged along the first direction DR1.

When each of the pixels PX includes three subpixels SPX1 through SPX3, the first subpixel SPX1 may output light of a first color, the second subpixel SPX2 may output light of a second color, and the third subpixel SPX3 may output light of a third color. Here, the light of the first color may be light in a red wavelength band, the light of the second color may be light in a green wavelength band, and the light of the third color may be light in a blue wavelength band. For example, the blue wavelength band may indicate that a main peak wavelength of light is included in a wavelength band of about 370 to 460 nm, the green wavelength band may indicate that a main peak wavelength of light is included in a wavelength band of about 480 to 560 nm, and the red wavelength band may indicate that a main peak wavelength of light is included in a wavelength band of about 600 to 750 nm.

Alternatively, when each of the pixels PX includes four subpixels, a first subpixel may output light of the first color, a second subpixel and a fourth subpixel may output light of the second color, and a third subpixel may output light of the third color. Alternatively, the first subpixel may output light of the first color, the second subpixel may output light of the second color, the third subpixel may output light of the third color, and the fourth subpixel may output light of a fourth color. Here, the light of the fourth color may be white light.

The first subpixel SPX1 includes a first pixel electrode PXE1, a plurality of light emitting elements LE, and a first light conversion layer QDL1. The second subpixel SPX2 includes a second pixel electrode PXE2, a plurality of light emitting elements LE, and a second light conversion layer QDL2. The third subpixel SPX3 includes a third pixel electrode PXE3, a plurality of light emitting elements LE, and a light transmission layer TPL (or a third light conversion layer).

Each of the first pixel electrode PXE1, the second pixel electrode PXE2, and the third pixel electrode PXE3 may be shaped like a rectangular plane having short sides in the first direction DR1 and long sides in the second direction DR2. The area of the first subpixel SPX1, the area of the second subpixel SPX2, and the area of the third subpixel SPX3 may be set according to the light conversion efficiency of the first light conversion layer QDL1 and the light conversion efficiency of the second light conversion layer QDL2. For example, the lower the light conversion efficiency, the larger the area of a subpixel.

For example, as illustrated in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1, and the area of the first pixel electrode PXE1 may be larger than the area of the third pixel electrode PXE3.

Each of the pixel electrodes PXE1 through PXE3 may be electrically connected to at least one transistor through a pixel connection hole CT1/CT2/CT3. For example, each of the pixel electrodes PXE1 through PXE3 may be electrically connected to a first electrode of the fourth transistor ST4 (see FIG. 4) and the second electrode of the sixth transistor ST6 (see FIG. 4) of a corresponding subpixel.

A plurality of light emitting elements LE may be disposed on each of the pixel electrodes PXE1 through PXE3. The same number of light emitting elements LE may be disposed on each of the pixel electrodes PXE1 through PXE3. For example, two light emitting elements LE may be disposed on each of the pixel electrodes PXE1 through PXE3. The light emitting elements LE may emit light of the third color, for example, light in the blue wavelength band, but the present disclosure is not limited thereto. If the light emitting elements LE of the first subpixel SPX1 emit light of the first color, the light emitting elements LE of the second subpixel SPX2 emit light of the second color, and the light emitting elements LE of the third subpixel SPX3 emit light of the third color, the light conversion layers QDL1 and QDL2 and the light transmission layer TPL may be omitted.

The first light conversion layer QDL1 may completely overlap the first pixel electrode PXE1 and the light emitting elements LE of the first subpixel SPX1. The area of the first light conversion layer QDL1 may be larger than the area of the first pixel electrode PXE1. The first light conversion layer QDL1 may convert and/or shift a peak wavelength of incident light into another specific peak wavelength and output light of the specific peak wavelength. For example, the first light conversion layer QDL1 may convert and/or shift light of the third color emitted from the light emitting elements LE of the first subpixel SPX1 into light of the first color.

The second light conversion layer QDL2 may completely overlap the second pixel electrode PXE2 and the light emitting elements LE of the second subpixel SPX2. The area of the second light conversion layer QDL2 may be larger than the area of the second pixel electrode PXE2. The second light conversion layer QDL2 may convert and/or shift a peak wavelength of incident light into another specific peak wavelength and output light of the specific peak wavelength. For example, the second light conversion layer QDL2 may convert and/or shift light of the third color emitted from the light emitting elements LE of the second subpixel SPX2 into light of the second color.

The light transmission layer TPL may completely overlap the third pixel electrode PXE3 and the light emitting elements LE of the third subpixel SPX3. The light transmission layer TPL may transmit incident light as it is. For example, the light transmission layer TPL may transmit light of the third color emitted from the light emitting elements LE of the third subpixel SPX3 as it is.

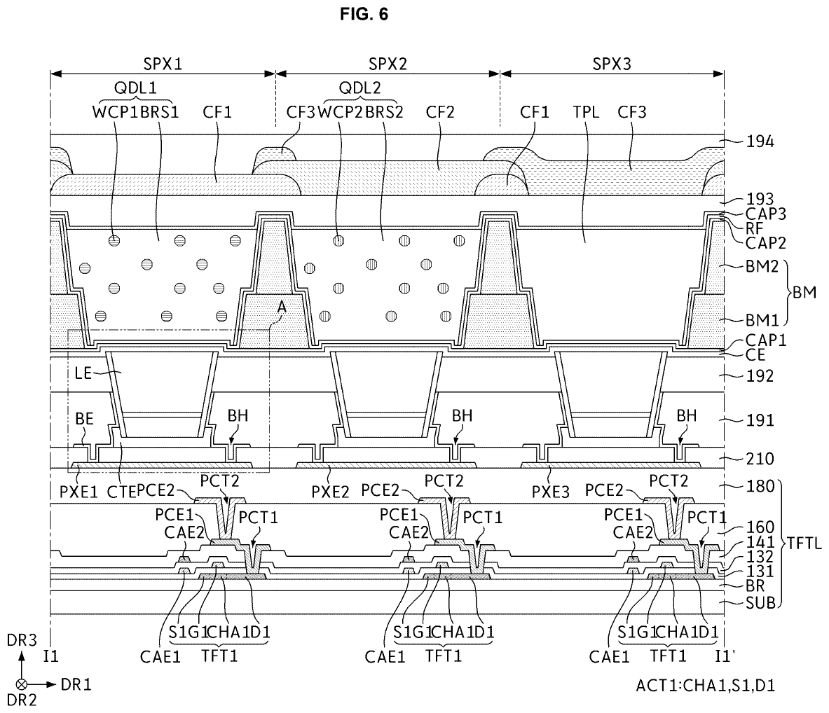

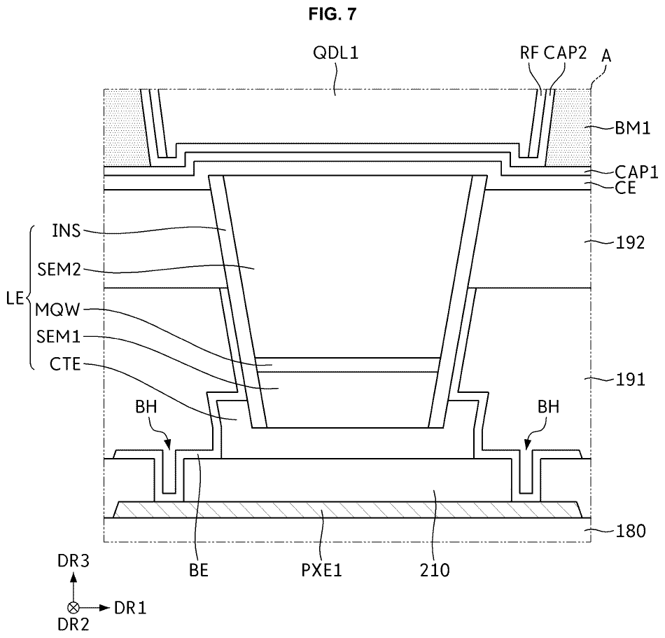

FIG. 6 is a cross-sectional view illustrating an example of a cross section of the display panel 100 corresponding to the line I1-I1′ of FIG. 5. FIG. 7 is a detailed cross-sectional view of an example of an area A of FIG. 6.

Referring to FIGS. 6 and 7, a substrate SUB may be made of an insulating material such as glass and/or polymer resin. When the substrate SUB is made of polymer resin, it may be a flexible substrate that can be stretched. The polymer resin may be acryl resin, epoxy resin, phenolic resin, polyamide resin, and/or polyimide resin.

A barrier layer BR may be disposed on the substrate SUB. The barrier layer BR is a layer for protecting transistors of a thin-film transistor layer TFTL and light emitting elements LE on the thin-film transistor layer TFTL from moisture introduced through the substrate SUB, which is vulnerable to moisture penetration. The barrier layer BR may be composed of a plurality of inorganic layers stacked alternately.

Thin-film transistors TFT1 may be disposed on the barrier layer BR. Each of the thin-film transistors TFT1 may be one of the fourth transistor ST4 and the sixth transistor ST6 illustrated in FIG. 4. Each of the thin-film transistors TFT1 may include a first active layer ACT1 and a first gate electrode G1.

The first active layer ACT1 of each of the thin-film transistors TFT1 may be disposed on the barrier layer BR. The first active layer ACT1 of each of the thin-film transistors TFT1 may include polycrystalline silicon, monocrystalline silicon, low-temperature polycrystalline silicon, and/or amorphous silicon. Alternatively, the first active layer ACT1 of each of the thin-film transistors TFT1 may be made of an oxide semiconductor including IGZO (indium (In), gallium (Ga), zinc (Zn) and oxygen (O)), IGZTO (indium (In), gallium (Ga), zinc (Zn), tin (Sn) and oxygen (O)), and/or IGTO (indium (In), gallium (Ga), tin (Sn) and oxygen (O)).

The first active layer ACT1 may include a first channel region CHA1, a first source region S1, and a first drain region D1. The first channel region CHA1 may be a region overlapped by the first gate electrode G1 in the third direction DR3, which is the thickness direction of the substrate SUB. The first source region S1 may be disposed on a side of the first channel region CHA1, and the first drain region D1 may be disposed on the other side of the first channel region CHA1. The first source region S1 and the first drain region D1 may be regions not overlapped by the first gate electrode G1 in the third direction DR3. The first source region S1 and the first drain region D1 may be regions formed to have conductivity by doping a semiconductor material with ions.

A first gate insulating layer 131 may be disposed on the first channel regions CHA1, the first source regions S1, and the first drain regions D1 of the thin-film transistors TFT1 and the barrier layer BR.

A first gate metal layer may be disposed on the first gate insulating layer 131. The first gate metal layer may include the first gate electrodes G1 of the thin-film transistors TFT1 and first capacitor electrodes CAE1. The first gate electrodes G1 may overlap the first active layers ACT1 in the third direction DR3. In FIG. 6, the first gate electrodes G1 and the first capacitor electrodes CAE1 are spaced (e.g., spaced apart) from each other. However, the first gate electrodes G1 and the first capacitor electrodes CAE1 may also be connected to each other. Alternatively, when each of the thin-film transistors TFT1 is the fourth transistor ST4 or the sixth transistor ST6 of FIG. 4, the first gate electrodes G1 and the first capacitor electrodes CAE1 may be separated from each other.

A second gate insulating layer 132 may be disposed on the first gate electrodes G1 of the thin-film transistors TFT1, the first capacitor electrodes CAE1, and the first gate insulating layer 131.

A second gate metal layer may be disposed on the second gate insulating layer 132. The second gate metal layer may include second capacitor electrodes CAE2. The second capacitor electrodes CAE2 may overlap the first capacitor electrodes CAE1 in the third direction DR3. Because the second gate insulating layer 132 has a suitable dielectric constant (e.g., a predetermined dielectric constant), capacitors C1 (see FIG. 4) may be formed by the first capacitor electrodes CAE1, the second capacitor electrodes CAE2, and the second gate insulating layer 132 disposed between them.

A first interlayer insulating layer 141 may be disposed on the second capacitor electrodes CAE2 and the second gate insulating layer 132.

A first data metal layer may be disposed on the interlayer insulating layer 141. The first data metal layer may include first source connection electrodes PCE1. The first source connection electrodes PCE1 may be connected to the first drain regions D1 of the first active layers ACT1 through first source contact holes PCT1 penetrating the first gate insulating layer 131, the second gate insulating layer 132, and the interlayer insulating layer 141.

A first organic layer 160 may be disposed on the first source connection electrodes PCE1 and the interlayer insulating layer 141 to flatten steps caused by the thin-film transistors TFT1.

A second data metal layer may be disposed on the first organic layer 160. The second data metal layer may include second source connection electrodes PCE2. The second source connection electrodes PCE2 may be connected to the first source connection electrodes PCE1 through second source contact holes PCT2 penetrating the first organic layer 160.

A second organic layer 180 may be disposed on the second source connection electrodes PCE2 and the first organic layer 160.

The barrier layer BR, the first gate insulating layer 131, the second gate insulating layer 132, and the interlayer insulating layer 141 may be made of an inorganic layer, for example, a silicon nitride layer, a silicon oxynitride layer, a silicon oxide layer, a titanium oxide layer, and/or an aluminum oxide layer.

The first gate metal layer, the second gate metal layer, the first data metal layer, and the second data metal layer may each be a single layer or a multilayer made of molybdenum (Mo), aluminum (AI), chromium (Cr), gold (Au), titanium (Ti), nickel (Ni), neodymium (Nd), copper (Cu), and/or alloys thereof.

The first organic layer 160 and the second organic layer 180 may be made of an organic layer such as acryl resin, epoxy resin, phenolic resin, polyamide resin, and/or polyimide resin.

A light emitting element layer may be disposed on the second organic layer 180. The light emitting element layer may include pixel electrodes PXE1 through PXE3, light emitting elements LE, a common electrode CE, and organic layers 191, 192, and 210.

A pixel electrode layer may be disposed on the second organic layer 180. The pixel electrode layer may include a first pixel electrode PXE1, a second pixel electrode PXE2, and a third pixel electrode PXE3. Each of the pixel electrodes PXE1 through PXE3 may be connected to a second source connection electrode PCE2 through a pixel connection hole CT1/CT2/CT3 (see FIG. 5) penetrating the second organic layer 180. Each of the pixel electrodes PXE1 through PXE3 may be connected to the first source region S1 (or a first electrode) or the first drain region D1 (or a second electrode) of a thin-film transistor TFT1 through a first source connection electrode PCE1 and a second source connection electrode PCE2. Therefore, a voltage controlled by a thin-film transistor TFT1 may be applied to each of the pixel electrodes PXE1 through PXE3.

The pixel electrode layer may be a single layer or a multilayer made of molybdenum (Mo), aluminum (AI), chromium (Cr), gold (Au), titanium (Ti), nickel (Ni), neodymium (Nd), copper (Cu), and/or alloys thereof. For example, the pixel electrode layer may be made of copper (Cu) with low sheet resistance in order to lower the resistance of each of the pixel electrodes PXE1 through PXE3.

An organic layer 210 may be disposed on each of the pixel electrodes PXE1 through PXE3 and the second organic layer 180. The organic layer 210 temporarily fixes or attaches a plurality of light emitting elements LE to prevent the light emitting elements LE from tilting or falling during a process of transferring the light emitting elements LE to the display panel 100. That is, the organic layer 210 may be a layer for temporarily attaching a plurality of light emitting elements LE onto each of the pixel electrodes PXE1 through PXE3. To facilitate the temporary adhesion, the organic layer 210 may be thicker than each of the pixel electrodes PXE1 through PXE3 and thicker than contact electrodes CTE.

The organic layer 210 may be a photosensitive organic layer such as photoresist. Alternatively, the organic layer 210 may be made of acryl resin, epoxy resin, phenolic resin, polyamide resin, and/or polyimide resin.

The light emitting elements LE may be disposed on the organic layer 210. In FIG. 6, each of the light emitting elements LE is a vertical type micro-light emitting diode extending in the third direction DR3. The vertical type micro-light emitting diode refers to a light emitting diode having a structure in which a first semiconductor layer SEM1, an active layer MQW, and a second semiconductor layer SEM2 are sequentially disposed along the third direction DR3, which is a vertical direction.

Each of the light emitting elements LE may have a reverse-tapered cross-sectional shape. For example, each of the light emitting elements LE may have a trapezoidal cross-sectional shape whose upper surface is wider than a lower surface.

Each of the light emitting elements LE may be made of an inorganic material such as gallium nitride (GaN). Each of the light emitting elements LE may have a length of several to hundreds of um in each of the first direction DR1, the second direction DR2, and the third direction DR3. For example, each of the light emitting elements LE may have a length of about 100 μm or less in each of the first direction DR1, the second direction DR2, and the third direction DR3.

Each of the light emitting elements LE may be grown on a semiconductor substrate such as a silicon substrate and/or a sapphire substrate. The light emitting elements LE may be directly transferred from the semiconductor substrate onto the pixel electrodes PXE1 through PXE3 of the display panel 100. Alternatively, the light emitting elements LE may be transferred onto the pixel electrodes PXE1 through PXE3 of the display panel 100 through an electrostatic method using an electrostatic head and/or a stamp method using an elastic polymer material, such as PDMS and/or silicon, as a transfer substrate.

Each of the light emitting elements LE may include a contact electrode CTE, the first semiconductor layer SEM1, the active layer MQW, the second semiconductor layer SEM2, and a protective layer INS.

The contact electrode CTE may be disposed on the entire lower surface of the first semiconductor layer SEM1 and a portion of each side surface (e.g., each outer peripheral surface) of the first semiconductor layer SEM1. In addition, the contact electrode CTE may be disposed on the protective layer INS disposed on the side surfaces (e.g., outer peripheral surfaces) of the first semiconductor layer SEM1. The contact electrode CTE may be disposed on the organic layer 210. The contact electrode CTE may include molybdenum (Mo), aluminum (Al), chromium (Cr), gold (Au), titanium (Ti), nickel (Ni), neodymium (Nd), and/or copper (Cu).

The first semiconductor layer SEM1 may be disposed on the contact electrode CTE. A length of the lower surface of the first semiconductor layer SEM1 in the first direction DR1 or in the second direction DR2 may be smaller than a length of the contact electrode CTE in the first direction DR1 or in the second direction DR2. The first semiconductor layer SEM1 may be made of GaN doped with a first conductivity type dopant such as Mg, Zn, Ca, Sr, and/or Ba.

The active layer MQW may be disposed on the first semiconductor layer SEM1. The active layer MQW may emit light through combination of electron-hole pairs according to electrical signals received through the first semiconductor layer SEM1 and the second semiconductor layer SEM2.

The active layer MQW may include a material having a single or multiple quantum well structure. When the active layer MQW includes a material having a multiple quantum well structure, it may be a structure in which a plurality of well layers and a plurality of barrier layers are alternately stacked. Here, the well layers may be made of InGaN, and the barrier layers may be made of GaN or AlGaN, but the present disclosure is not limited thereto. Alternatively, the active layer MQW may be a structure in which a semiconductor material having a large band gap energy and a semiconductor material having a small band gap energy are alternately stacked or may include different group III to V semiconductor materials depending on the wavelength band of light that it emits.

When the active layer MQW includes InGaN, the color of light that it emits may vary according to indium content. For example, as the indium content increases, the wavelength band of light emitted from the active layer MQW may move to the red wavelength band, and as the indium content decreases, the wavelength band of light emitted from the active layer MQW may move to the blue wavelength band. For example, the indium content of the active layer MQW of a light emitting element LE that emits light of the third color (e.g., light in the blue wavelength band) may be about 10 to 20 wt %.

The second semiconductor layer SEM2 may be disposed on the active layer MQW. The second semiconductor layer SEM2 may be doped with a second conductivity type dopant such as Si, Ge, and/or Sn. For example, the second semiconductor layer SEM2 may be n-GaN doped with n-type Si.

An electron blocking layer may be disposed between the first semiconductor layer SEM1 and the active layer MQW. The electron blocking layer may be a layer for suppressing or preventing too many electrons from flowing into the active layer MQW. For example, the electron blocking layer may be AlGaN and/or p-AlGaN doped with p-type Mg. The electron blocking layer can be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be made of InGaN and/or GaN. The superlattice layer can be omitted.

The protective layer INS may be disposed on the side surfaces (e.g., outer peripheral surfaces) of the first semiconductor layer SEM1, side surfaces (e.g., outer peripheral surfaces) of the active layer MQW, and side surfaces (e.g., outer peripheral surfaces) of the second semiconductor layer SEM2. The protective layer INS may be a layer for protecting side surfaces (e.g., outer peripheral surfaces) of each light emitting element LE. The protective layer INS may be made of an inorganic layer, for example, a silicon nitride layer, a silicon oxynitride layer, a silicon oxide layer, a titanium oxide layer, and/or an aluminum oxide layer.

A connection electrode BE connects the contact electrode CTE of each light emitting element LE to one of the pixel electrodes PXE1 through PXE3. The connection electrode BE may be connected to one of the pixel electrodes PXE1 through PXE3 exposed through a connection hole BH penetrating the organic layer 210. In addition, the connection electrode BE may be disposed on an upper surface of the organic layer 210 and side surfaces of the contact electrode CTE. In addition, the connection electrode BE may be disposed on a portion of the side surfaces (e.g., the outer peripheral surfaces) of each light emitting element LE. For example, the connection electrode BE may be disposed on a portion of the protective layer INS of each light emitting element LE.

The connection electrode BE may include molybdenum (Mo), aluminum (Al), chromium (Cr), gold (Au), titanium (Ti), nickel (Ni), neodymium (Nd), and/or copper (Cu). Alternatively, the connection electrode BE may be made of a transparent conductive material (TCO) that can transmit light, such as indium tin oxide (ITO) and/or indium zinc oxide (IZO).

When the connection electrode BE is made of a metal material with high reflectivity such as aluminum (Al), light travelling in a lateral direction of each light emitting element LE from among light emitted from the active layer MQW of the light emitting element LE may be reflected by the connection electrode BE toward the top of the light emitting element LE. Accordingly, a loss of light of the light emitting element LE can be reduced, and thus the light efficiency of the light emitting element LE can be increased.

A third organic layer 191 may partially cover the side surfaces of the light emitting elements LE. In addition, the third organic layer 191 may cover the connection electrodes BE, but at least a portion of each of the connection electrodes BE may be exposed without being covered by the third organic layer 191.

A fourth organic layer 192 may be disposed on the third organic layer 191. The fourth organic layer 192 may partially cover the side surfaces of each of the light emitting elements LE. The fourth organic layer 192 may be disposed on at least a portion of each of the connection electrodes BE exposed without being covered by the third organic layer 191. An upper surface of each of the light emitting elements LE may be exposed without being covered by the fourth organic layer 192.

The third organic layer 191 and the fourth organic layer 192 may be made of an organic layer such as acryl resin, epoxy resin, phenolic resin, polyamide resin, and/or polyimide resin.

The third organic layer 191 and the fourth organic layer 192 are layers for flattening steps caused by the light emitting elements LE. If the third organic layer 191 is high enough to cover most of the side surfaces of each of the light emitting elements LE, the fourth organic layer 192 may be omitted.

The common electrode CE may be disposed on the upper surface of each of the light emitting elements LE and an upper surface of the fourth organic layer 192. The common electrode CE may be a common layer commonly formed in a first subpixel SPX1, a second subpixel SPX2, and a third subpixel SPX3. The common electrode CE may be made of a transparent conductive material (TCO) that can transmit light, such as indium tin oxide (ITO) and/or indium zinc oxide (IZO).

The pixel electrodes PXE1 through PXE3 may be referred to as anodes or first electrodes, and the common electrode CE may be referred to as a cathode or a second electrode.

A first capping layer CAP1 may be disposed on the common electrode CE.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be separated and/or partitioned by the light blocking layer BM. Therefore, the first light conversion layer QDL1 may be disposed on the first capping layer CAP1 in the first subpixel SPX1, the second light conversion layer QDL2 may be disposed on the first capping layer CAP1 in the second subpixel SPX2, and the light transmission layer TPL may be disposed on the first capping layer CAP1 in the third subpixel SPX3. The light blocking layer BM may overlap the third organic layer 191 and the fourth organic layer 192 in the third direction DR3 and may not overlap the light emitting elements LE.

The first light conversion layer QDL1 may convert a portion of light of the third color (e.g., light in the blue wavelength band) incident from a light emitting element LE into light of the first color (e.g., light in the red wavelength band). The first light conversion layer QDL1 may include a first base resin BRS1 and first wavelength conversion particles WCP1. The first base resin BRS1 may include a light-transmitting organic material. The first wavelength conversion particles WCP1 may convert a portion of the light of the third color (e.g., light in the blue wavelength band) incident from the light emitting element LE into the light of the first color (e.g., light in the red wavelength band).

The second light conversion layer QDL2 may convert a portion of light of the third color (e.g., light in the blue wavelength band) incident from a light emitting element LE into light of the second color (e.g., light in the green wavelength band). The second light conversion layer QDL2 may include a second base resin BRS2 and second wavelength conversion particles WCP2. The second base resin BRS2 may include a light-transmitting organic material. The second wavelength conversion particles WCP2 may convert a portion of the light of the third color (e.g., light in the blue wavelength band) incident from the light emitting element LE into the light of the second color (e.g., light in the green wavelength band).

The light transmission layer TPL may include a light-transmitting organic material.

For example, the first base resin BRS1, the second base resin BRS2, and the light transmission layer TPL may include epoxy resin, acrylic resin, cardo resin, and/or imide resin. The first and second wavelength conversion particles WCP1 and WCP2 may be quantum dots, quantum rods, fluorescent materials, and/or phosphorescent materials.

The light blocking layer BM may include a first light blocking layer BM1 and a second light blocking layer BM2 stacked sequentially. A length of the first light blocking layer BM1 in the first direction DR1 and/or a length of the first light blocking layer BM1 in the second direction DR2 may be greater than a length of the second light blocking layer BM2 in the first direction DR1 and/or a length of the second light blocking layer BM2 in the second direction DR2. The first light blocking layer BM1 and the second light blocking layer BM2 may be made of an organic layer such as acryl resin, epoxy resin, phenolic resin, polyamide resin, and/or polyimide resin. The first light blocking layer BM1 and the second light blocking layer BM2 may include a light blocking material to prevent light of a light emitting element LE of any one subpixel from travelling to a neighboring subpixel. For example, the first light blocking layer BM1 and the second light blocking layer BM2 may include an inorganic black pigment such as carbon black and/or an organic black pigment.

A second capping layer CAP2 may be disposed on the first capping layer CAP1 and the light blocking layer BM. The second capping layer CAP2 may be disposed on side and upper surfaces of the light blocking layer BM. For example, the second capping layer CAP2 may be disposed on side surfaces of the first light blocking layer BM1 and side and upper surfaces of the second light blocking layer BM2 and on the first capping layer CAP1.

A reflective layer RF may be disposed between the light blocking layer BM and the first light conversion layer QDL1, between the light blocking layer BM and the second light conversion layer QDL2, and between the light blocking layer BM and the light transmission layer TPL. The reflective layer RF may be disposed on the second capping layer CAP2 disposed on the side surfaces of the first light blocking layer BM1 and the side surfaces of the second light blocking layer BM2. The reflective layer RF may reflect light travelling in the lateral direction from the first light conversion layer QDL1, the second light conversion layer QDL2, and the light transmission layer TPL.

The reflective layer RF may include a metal material with high reflectivity, such as aluminum (Al). A thickness of the reflective layer RF may be about 0.1 μm.

Alternatively, to serve as distributed Bragg reflectors, the reflective layer RF may include M (M is an integer of 2 or more) pairs of first and second layers having different refractive indices. In this case, M first layers and M second layers may be arranged alternately. The first and second layers may be made of an inorganic layer, for example, a silicon nitride layer, a silicon oxynitride layer, a silicon oxide layer, a titanium oxide layer, and/or an aluminum oxide layer.

A third capping layer CAP3 may be disposed on the reflective layer RF, the second capping layer CAP2, the first light conversion layer QDL1, the second light conversion layer QDL2, and the light transmission layer TPL.

The first capping layer CAP1, the second capping layer CAP2, and the third capping layer CAP3 may be made of an inorganic layer, for example, a silicon nitride layer, a silicon oxynitride layer, a silicon oxide layer, a titanium oxide layer, and/or an aluminum oxide layer. The first light conversion layer QDL1, the second light conversion layer QDL2, and the light transmission layer TPL may be encapsulated by the first capping layer CAP1, the second capping layer CAP2, and the third capping layer CAP3.

A fifth organic layer 193 may be disposed on the third capping layer CAP3. A plurality of color filters CF1 through CF3 may be disposed on the fifth organic layer 193. The color filters CF1 through CF3 may include first color filters CF1, second color filters CF2, and third color filters CF3.

A first color filter CF1 disposed in the first subpixel SPX1 may transmit light of the first color (e.g., light in the red wavelength band) and absorb and/or block light of the third color (e.g., light in the blue wavelength band). Therefore, the first color filter CF1 may transmit the light of the first color (e.g., light in the red wavelength band) into which a portion of the light of the third color (e.g., light in the blue wavelength band) emitted from a light emitting element LE has been converted by the first light conversion layer QDL1 and may absorb and/or block the light of the third color (e.g., light in the blue wavelength band) which has not been converted by the first light conversion layer QDL1. Accordingly, the first subpixel SPX1 may output the light of the first color (e.g., light in the red wavelength band).

A second color filter CF2 disposed in the second subpixel SPX2 may transmit light of the second color (e.g., light in the green wavelength band) and absorb and/or block light of the third color (e.g., light in the blue wavelength band). Therefore, the second color filter CF2 may transmit the light of the second color (e.g., light in the green wavelength band) into which a portion of the light of the third color (e.g., light in the blue wavelength band) emitted from a light emitting element LE has been converted by the second light conversion layer QDL2 and may absorb or block the light of the third color (e.g., light in the blue wavelength band) which has not been converted by the second light conversion layer QDL2. Accordingly, the second subpixel SPX2 may output the light of the second color (e.g., light in the green wavelength band).

A third color filter CF3 disposed in the third subpixel SPX3 may transmit light of the third color (e.g., light in the blue wavelength band). Therefore, the third color filter CF3 may transmit the light of the third color (e.g., light in the blue wavelength band) that passes through the light transmission layer TPL after being emitted from a light emitting element LE. Accordingly, the third subpixel SPX3 may emit the light of the third color (e.g., light in the blue wavelength band).

The first color filter CF1, the second color filter CF2, and the third color filter CF3 overlapping each other in the third direction DR3 may overlap the light blocking layer BM in the third direction DR3.

A sixth organic layer 194 for planarization may be disposed on the color filters CF1 through CF3.

The fifth organic layer 193 and the sixth organic layer 194 may be made of acryl resin, epoxy resin, phenolic resin, polyamide resin, and/or polyimide resin.

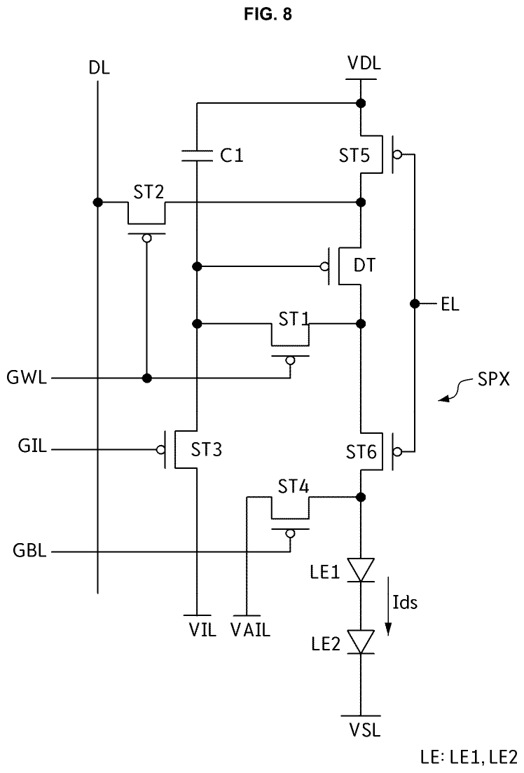

FIG. 8 is an equivalent circuit diagram of a subpixel SPX according to one or more embodiments. FIG. 8 shows an embodiment different from the embodiment of FIG. 4 in relation to a light emitting element LE used as a light source of the subpixel SPX. In the description of the following embodiments, descriptions overlapping those of the previously described embodiments will be omitted.

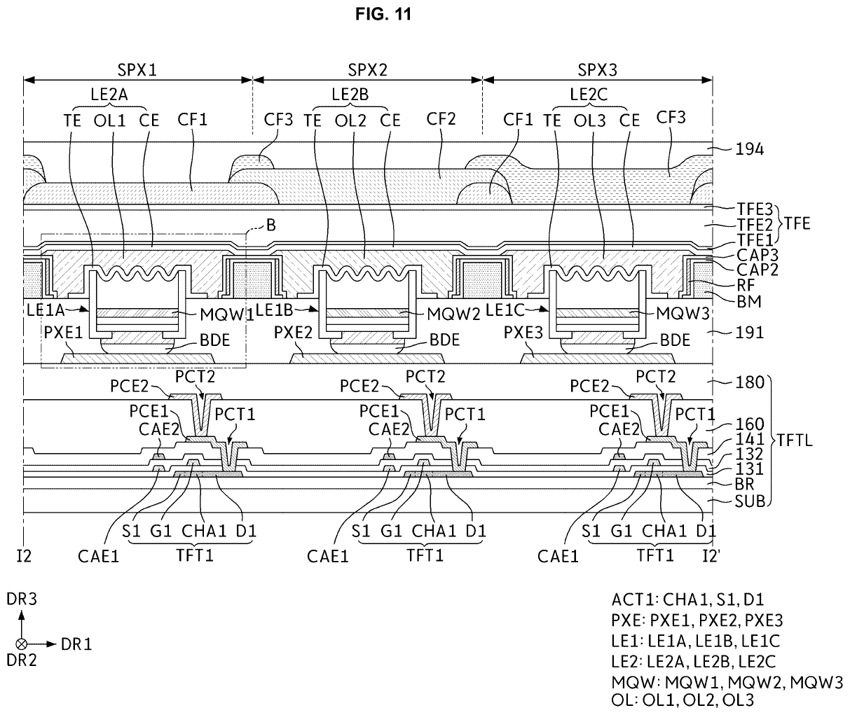

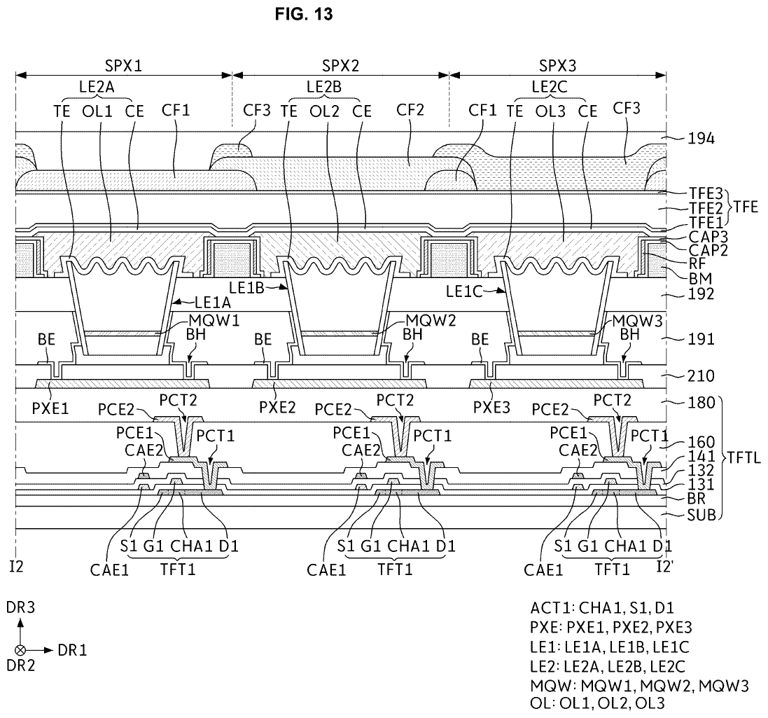

Referring to FIG. 8, the subpixel SPX according to the embodiment may include a plurality of light emitting elements LE including a first light emitting element LE1 and a second light emitting element LE2 connected to each other in series. For example, the first light emitting element LE1 and the second light emitting element LE2 may be connected to each other in series between a pixel circuit, which includes a driving transistor DT, switch elements (e.g., first through sixth transistors ST1 through ST6) and a capacitor C1, and a second power line VSL. In describing embodiments, a “connection” may include a direct connection and/or an indirect connection and may include electrical and/or physical connection. A driving current Ids corresponding to a data voltage of a data line DL may be supplied to the first light emitting element LE1 through each pixel electrode, may sequentially pass through the first light emitting element LE1 and the second light emitting element LE2, and then may flow to the second power line VSL through a common electrode (e.g., a common electrode CE of FIG. 11 or FIG. 13).

Although FIG. 8 discloses an embodiment in which the subpixel SPX includes a single first light emitting element LE1 and a single second light emitting element LE2, the present disclosure is not limited thereto. For example, the subpixel SPX may also include at least two first light emitting elements LE1 connected (e.g., connected in parallel) between the pixel circuit and the second light emitting element LE2. Similarly, the subpixel SPX may also include at least two second light emitting elements LE2 connected (e.g., connected in parallel) between at least one first light emitting element LE1 and the second power line VSL.

For example, a light emitting unit of the subpixel SPX (e.g., a light emitting unit including light emitting elements LE constituting the light source of the subpixel SPX) may include a first series unit including at least one first light emitting element LE1 and a second series unit including at least one second light emitting element LE2. Accordingly, the light emitting unit of the subpixel SPX may include at least two light emitting elements LE connected to each other in series or in series-parallel.

In one or more embodiments, the first light emitting element LE1 and the second light emitting element LE2 may be different types and/or sizes of light emitting elements LE. For example, the first light emitting element LE1 may be an inorganic light emitting element (e.g., an inorganic light emitting diode) including an inorganic light emitting layer made of gallium nitride (GaN) and/or other inorganic materials, and the second light emitting element LE2 may be an organic light emitting element (e.g., an organic light emitting diode (OLED)) including an organic light emitting layer made of an organic material (e.g., an organic material including a fluorescent and/or phosphorescent material that emits red, green, or blue light). Accordingly, the subpixel SPX may include a light emitting unit having a hybrid structure (or a tandem structure) including different types of light emitting elements LE.

In one or more embodiments, the first light emitting element LE1 may be a light emitting element made of gallium nitride (GaN) or other inorganic materials and having a length of about 100 μm or less in each of the first direction DR1, the second direction DR2, and the third direction DR3. For example, the first light emitting element LE1 may be a micro-light emitting diode including a micro-inorganic light emitting layer. In one or more embodiments, the second light emitting element LE2 may be an organic light emitting diode (OLED) including an organic light emitting layer. The second light emitting element LE2 may have a larger area than the first light emitting element LE1, but the present disclosure is not limited thereto. The sizes and types of the first light emitting element LE1 and the second light emitting element LE2 may vary according to embodiments.

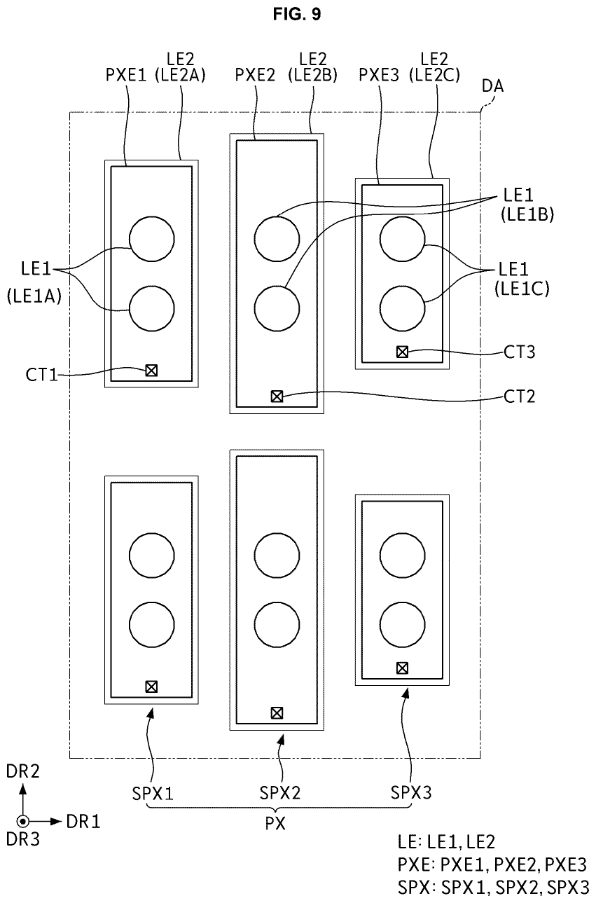

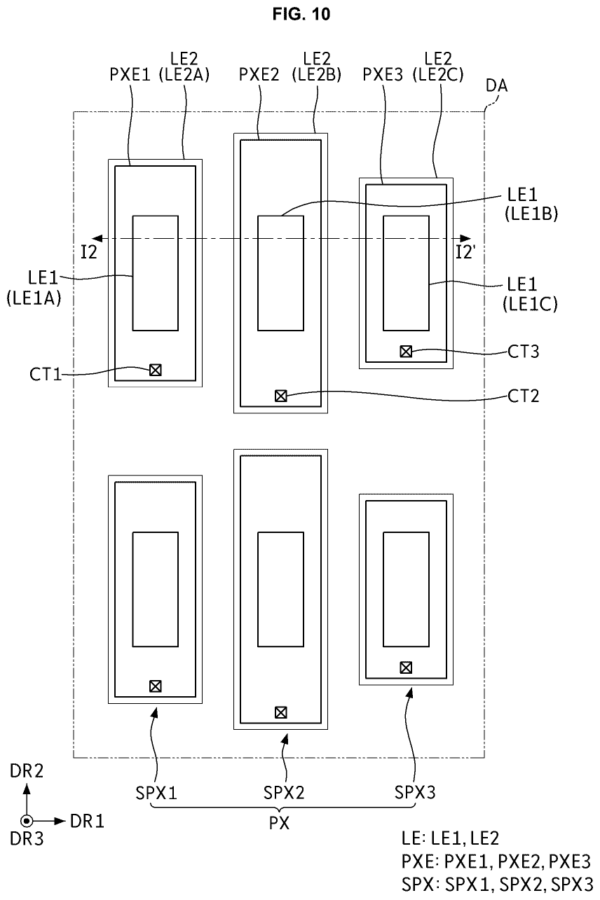

FIG. 9 is a layout view illustrating pixels PX of a display area DA according to one or more embodiments. FIG. 10 is a layout view illustrating pixels PX of a display area DA according to one or more embodiments. FIGS. 9 and 10 show embodiments different from the embodiment of FIG. 5 in that each subpixel SPX includes a first light emitting element LE1 and a second light emitting element LE2. In addition, FIGS. 9 and 10 disclose different embodiments in relation to the first light emitting element LE1.

Referring to FIGS. 9 and 10, each subpixel SPX may include a pixel electrode PXE and the first and second light emitting elements LE1 and LE2 disposed on the pixel electrode PXE. FIGS. 9 and 10 disclose embodiments in which a first subpixel SPX1, a second subpixel SPX2, and a third subpixel SPX3 (or emission areas of the first subpixel SPX1, the second subpixel SPX2, and the third subpixel SPX3) have different sizes. However, the present disclosure is not limited thereto. For example, the first subpixel SPX1, the second subpixel SPX2, and the third subpixel SPX3 (or the emission areas of the first subpixel SPX1, the second subpixel SPX2, and the third subpixel SPX3) may also have substantially the same or similar size. For example, the subpixels SPX may be formed in an appropriate size and/or ratio in consideration of the light efficiency and/or white balance of the subpixels SPX.

The first light emitting element LE1 and the second light emitting element LE2 disposed in each subpixel SPX may overlap each other (e.g., in the third direction DR3). For example, the first light emitting element LE1 may be disposed on a pixel electrode PXE, and the second light emitting element LE2 may be disposed on the first light emitting element LE1.

In one or more embodiments, as illustrated in FIG. 9, each subpixel SPX may include a plurality of first light emitting elements LE1 disposed and/or connected in parallel on a pixel electrode PXE. The second light emitting element LE2 may be disposed on the first light emitting elements LE1. In one or more embodiments, the second light emitting element LE2 may have a larger size (e.g., a larger area) than the first light emitting elements LE1 in a plan view and may cover the top of the first light emitting elements LE1.

Alternatively, as illustrated in FIG. 10, each subpixel SPX may include a single first light emitting element LE1 disposed on a pixel electrode PXE. The second light emitting element LE2 may be disposed on the single first light emitting element LE1. In one or more embodiments, the second light emitting element LE2 may have a larger size (e.g., a larger area) than the first light emitting element LE1 in a plan view and may cover the top of the first light emitting element LE1.

The first light emitting element LE1 may have a circular planar shape as illustrated in FIG. 9 or a quadrangular planar shape as illustrated in FIG. 10. Alternatively, the first light emitting element LE1 may have other planar shapes. For example, the shape of the first light emitting element LE1 may vary according to embodiments.

The first light emitting element LE1 may have a size that allows it to be appropriately or stably disposed inside a pixel electrode PXE or an emission area where the pixel electrode PXE is disposed. The shape and/or size of the first light emitting element LE1 may vary according to embodiments.

The second light emitting element LE2 may have a circular, elliptical, rectangular, square, or other planar shape. In one or more embodiments, the second light emitting element LE2 may have a planar shape that follows the planar shape of a pixel electrode PXE or the planar shape of an emission area where the pixel electrode PXE is disposed, but the present disclosure is not limited thereto. The emission area of each subpixel SPX may be an area where a pixel electrode PXE, the first light emitting element LE1, and the second light emitting element LE2 of the subpixel SPX are disposed and may be an area where light generated by the first light emitting element LE1 and the second light emitting element LE2 is emitted.

In one or more embodiments, the second light emitting element LE2 may have a size similar to that of each pixel electrode PXE. For example, an electrode (e.g., a connection electrode connecting the first light emitting element LE1 and the second light emitting element LE2 and utilized as an anode of the second light emitting element LE2) or an organic light emitting layer of the second light emitting element LE2 may have substantially the same or similar size as a pixel electrode PXE and may overlap the pixel electrode PXE. However, the shape, size, and/or position of the second light emitting element LE2 may vary according to embodiments.

In one or more embodiments, the second light emitting element LE2 may overlap a pixel connection hole CT1/CT2/CT3 of each subpixel SPX. However, the present disclosure is not limited thereto. The second light emitting element LE2 may not be directly connected to each pixel electrode PXE or each pixel connection hole CT1/CT2/CT3.

In one or more embodiments, subpixels SPX that emit light of different colors may include light emitting elements LE of different colors. For example, each subpixel SPX may include light emitting elements LE that emit light of a color or wavelength corresponding to its emission color.

In one or more embodiments, the first subpixel SPX1 may include a first light emitting element LE1A of a first color (e.g., a red micro-light emitting diode) and a second light emitting element LE2A of the first color (e.g., a red organic light emitting diode (OLED)). Accordingly, the first subpixel SPX1 may emit light of the first color (e.g., red light). The second subpixel SPX2 may include a first light emitting element LE1B of a second color (e.g., a green micro-light emitting diode) and a second light emitting element LE2B of the second color (e.g., a green organic light emitting diode (OLED)). Accordingly, the second subpixel SPX2 may emit light of the second color (e.g., green light). The third subpixel SPX3 may include a first light emitting element LE1C of a third color (e.g., a blue micro-light emitting diode) and a second light emitting element LE2C of the third color (e.g., a blue organic light emitting diode (OLED)). Accordingly, the third subpixel SPX3 may emit light of the third color (e.g., blue light).

In one or more embodiments, each subpixel SPX may not include the first light conversion layer QDL1, the second light conversion layer QDL2, or the light transmission layer TPL included in each subpixel SPX according to the embodiment of FIGS. 5 through 7. For example, when each subpixel SPX includes light emitting elements LE corresponding to its emission color, it may include an organic layer (e.g., an organic layer OL of FIG. 11) formed at a position corresponding to the first light conversion layer QDL1, the second light conversion layer QDL2, or the light transmission layer TPL of FIGS. 5 through 7 and including the organic light emitting layer of the second light emitting element LE2.

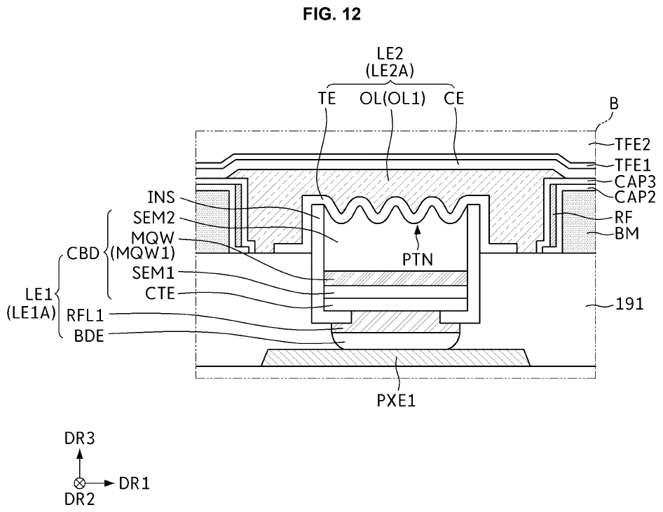

FIG. 11 is a cross-sectional view illustrating an example of a cross section of a display panel 100 corresponding to the line I2-I2′ of FIG. 10. FIG. 12 is a detailed cross-sectional view of an example of an area B of FIG. 11.

FIGS. 11 and 12 show a cross section of the display panel 100 in which each subpixel SPX includes a first light emitting element LE1 and a second light emitting element LE2 as in the embodiments of FIGS. 8 through 10. In addition, FIGS. 11 and 12 show an embodiment different from the embodiment of FIG. 6 in relation to a light emitting element layer including light emitting elements LE.

Referring to FIGS. 11 and 12, the first light emitting element LE1 and the second light emitting element LE2 of each subpixel SPX may be sequentially disposed on a pixel electrode PXE of each subpixel SPX. For example, at least one first light emitting element LE1A of a first color may be disposed on a first pixel electrode PXE1 of a first subpixel SPX1, and a second light emitting element LE2A of the first color may be disposed on the at least one first light emitting element LE1A of the first color. At least one first light emitting element LE1B of a second color may be disposed on a second pixel electrode PXE2 of a second subpixel SPX2, and a second light emitting element LE2B of the second color may be disposed on the at least one first light emitting element LE1B of the second color. At least one first light emitting element LE1C of a third color may be disposed on a third pixel electrode PXE3 of a third subpixel SPX3, and a second light emitting element LE2C of the third color may be disposed on the at least one first light emitting element LE1C of the third color. The first light emitting element LE1 and the second light emitting element LE2 of each subpixel SPX may be connected in series between a pixel electrode PXE and a common electrode CE of each subpixel SPX.

In one or more embodiments, the first light emitting elements LE1 may include bonding electrodes BDE, respectively, and may be placed or bonded on the pixel electrodes PXE (or bonding pads connected to the pixel electrodes PXE) by the bonding electrodes BDE, respectively. For example, the first light emitting elements LE1 can be stably placed and/or bonded on the pixel electrodes PXE using a bonding method such as eutectic bonding. When the first light emitting elements LE1 are directly placed and/or bonded on the pixel electrodes PXE (or the bonding pads), the display panel 100 may not include the organic layer 210 and the connection electrodes BE of FIGS. 6-7. In one or more embodiments, each of the pixel electrodes PXE may be, but is not limited to, a multilayer including metal. The type or structure of the first light emitting elements LE1 or the connection structure or method of the first light emitting elements LE1 and the pixel electrodes PXE may vary according to embodiments.

In one or more embodiments, each of the first light emitting elements LE1 may include a body portion CBD (e.g., a micro-light emitting diode chip body) and a bonding electrode BDE as illustrated in FIG. 12. In one or more embodiments, each of the first light emitting elements LE1 may further include a first reflective layer RFL1 disposed between the body portion CBD and the bonding electrode BDE. The first reflective layer RFL1 may be disposed below the body portion CBD.

The body portion CBD may include a first semiconductor layer SEM1, an active layer MQW, and a second semiconductor layer SEM2 sequentially disposed along a direction (e.g., the third direction DR3). For example, the first semiconductor layer SEM1, the active layer MQW, and the second semiconductor layer SEM2 may be sequentially disposed on a pixel electrode PXE.

The active layers MQW of the first light emitting elements LE1 of different colors may emit light of different colors. For example, the active layer MQW included in the first light emitting element LE1A of the first color may be a first inorganic light emitting layer MQW1 that emits light of the first color, and the active layer MQW included in the first light emitting element LE1B of the second color may be a second inorganic light emitting layer MQW2 that emits light of the second color. The active layer MQW included in the first light emitting element LE1C of the third color may be a third inorganic light emitting layer MQW3 that emits light of the third color. In one or more embodiments, the color of light emitted from each of the first light emitting elements LE1 may be adjusted or changed by adjusting the indium (In) content of a well layer (e.g., an InGaN layer) included in each of the active layers MQW of the first light emitting elements LE1.

In one or more embodiments, the body portion CBD may further include a contact electrode CTE disposed on a surface (e.g., a lower surface) of the first semiconductor layer SEM1 and a protective layer INS covering side surfaces (e.g., outer peripheral surfaces) of the contact electrode CTE, the first semiconductor layer SEM1, the active layer MQW and the second semiconductor layer SEM2. The protective layer INS may also partially cover the bottom surface of the contact electrode CTE.

In one or more embodiments, the contact electrode CTE may have a shape and/or size corresponding to those of the first semiconductor layer SEM1, the active layer MQW, and the second semiconductor layer SEM2. For example, the contact electrode CTE may be etched together with semiconductor layers on a semiconductor substrate on which the semiconductor layers for manufacturing the light emitting elements LE are grown. The etched semiconductor layers may include the first semiconductor layer SEM1, the active layer MQW, and the second semiconductor layer SEM2 of each of the light emitting elements LE, and the contact electrode CTE may be disposed on the first semiconductor layer SEM1, the active layer MQW, and the second semiconductor layer SEM2. The shape or size of the contact electrode CTE may vary according to embodiments.

In one or more embodiments, the protective layer INS may further cover the contact electrode CTE. For example, the protective layer INS may cover the side surfaces (e.g., the outer peripheral surfaces) of the contact electrode CTE, the first semiconductor layer SEM1, the active layer MQW, and the second semiconductor layer SEM2.

In one or more embodiments, the protective layer INS may partially cover a lower surface of the contact electrode CTE. For example, the protective layer INS may cover an edge portion of the lower surface of the contact electrode CTE and may include an opening exposing a central portion of the contact electrode CTE. However, the present disclosure is not limited thereto. For example, the protective layer INS may cover only the side surfaces (e.g., outer peripheral surfaces) of the contact electrode CTE or may not cover the contact electrode CTE.

In one or more embodiments, the body portion CBD may have a quadrangular cross-sectional shape such as a square, rectangular, or trapezoidal shape. For example, the body portion CBD may be a vertical type micro-light emitting diode chip having a square or rectangular cross-sectional shape. Alternatively, the body portion CBD may have a reverse-tapered (or tapered) trapezoidal cross-sectional shape as in the embodiment of FIG. 7. The type, shape, and/or size of the body portion CBD may vary according to embodiments.

The bonding electrode BDE may include a conductive material (e.g., a bonding metal) suitable for bonding. In one or more embodiments, the bonding electrode BDE may be disposed on a lower surface of the first reflective layer RFL1 and may be electrically connected to the contact electrode CTE through the first reflective layer RFL1. The bonding electrode BDE may be bonded onto a pixel electrode PXE and electrically connected to the pixel electrode PXE.

The first reflective layer RFL1 may be disposed on a lower surface of the body portion CBD. The first reflective layer RFL1 may include a metal with high light reflectivity. For example, the first reflective layer RFL1 may be composed of at least one metal layer including at least one of metals with high reflectivity, such as aluminum (Al), molybdenum (Mo), titanium (Ti), copper (Cu), silver (Ag), magnesium (Mg), platinum (Pt), palladium (Pd), gold (Au), nickel (Ni), neodymium (Nd), iridium (Ir) and/or chromium (Cr), or another reflective material. In one or more embodiments, the first reflective layer RFL1 may be, but is not limited to, a multilayer composed of a reflective metal layer and a conductive bonding layer disposed on at least one surface of the reflective metal layer.

Light generated in a light emitting element LE and then travelling toward the bottom of the body portion CBD may be reflected by the first reflective layer RFL1 toward the top of the light emitting element LE. Accordingly, the light output efficiency of the light emitting element LE can be increased.

In one or more embodiments, the first light emitting element LE1 of each subpixel SPX may include a textured pattern PTN (also referred to as a “pattern”, an “optical pattern”, or a “light-transmitting pattern”) at (e.g., formed on) a light output surface (e.g., an upper surface located opposite the bonding electrode BDE). For example, the upper surface of the first light emitting element LE1 including the textured pattern PTN may not be substantially flat and may have surface roughness. The textured pattern PTN may have a lens shape, a prism shape or other shapes and may include regular or irregular curves or irregularities.

In one or more embodiments, a semiconductor substrate for manufacturing the first light emitting element LE1 may be patterned to give roughness to a surface of the semiconductor substrate. Then, the second semiconductor layer SEM2, the active layer MQW, and the first semiconductor layer SEM1 may be sequentially grown on the semiconductor substrate and then etched to manufacture the first light emitting element LE1. Accordingly, the first light emitting element LE1 may include the textured pattern PTN on a surface where the second semiconductor layer SEM2 is disposed (e.g., the upper surface of the first light emitting element LE1 which faces the common electrode CE). The shape and size of the textured pattern PTN included in the first light emitting element LE1 or a process method or step for forming the textured pattern PTN may vary according to embodiments. For example, in one or more embodiments, the textured pattern PTN may be at (e.g., formed on) the upper surface of the first light emitting element LE1 by additionally performing a texturing process after the first light emitting element LE1 is manufactured.

Because the first light emitting element LE1 includes the textured pattern PTN at (e.g., formed on) its light output surface, the light output efficiency of the first light emitting element LE1 and a subpixel SPX including the same can be further improved.

In one or more embodiments, the first light emitting element LE1 of each subpixel SPX may further include a second reflective layer formed on its side surfaces. For example, the first light emitting element LE1 may further include the second reflective layer disposed on side surfaces of the protective layer INS. In one or more embodiments, the second reflective layer may be a distributed Bragg reflector (DBR) in which a low refractive index layer and a high refractive index layer including an insulating material are alternately disposed. However, the present disclosure is not limited thereto. For example, the second reflective layer may also include a metal with high reflectivity.

In one or more embodiments, when the first light emitting element LE1 includes the second reflective layer made of an insulating material, it may or may not include the protective layer INS. For example, the first light emitting element LE1 may include the second reflective layer disposed on the side surfaces (e.g., the outer peripheral surfaces) of the protective layer INS. Alternatively, the first light emitting element LE1 may not include the protective layer INS, and the second reflective layer may directly cover the side surfaces (e.g., the outer peripheral surfaces) of the contact electrode CTE, the first semiconductor layer SEM1, the active layer MQW, and the second semiconductor layer SEM2.

In one or more embodiments, the display panel 100 may not include the fourth organic layer 192 of FIG. 6 as illustrated in FIG. 11. For example, the fourth organic layer 192 may not be disposed on a third organic layer 191, and a portion of the first light emitting element LE1 may be disposed higher than the third organic layer 191 and thus may be surrounded by an organic layer OL of a second light emitting element LE2 or a light blocking layer BM. However, the present disclosure is not limited thereto. For example, in one or more embodiments, the display panel 100 may further include at least one organic layer, for example, the fourth organic layer 192 of FIG. 6 or FIG. 13 disposed on the third organic layer 191, and the first light emitting element LE1 may be substantially entirely surrounded by the third organic layer 191 and the fourth organic layer 192.

Additionally, FIG. 11 shows an embodiment in which the third organic layer 191 is formed lower than the first light emitting elements LE1 to partially cover the side surfaces (e.g., the outer peripheral surfaces) of each of the first light emitting elements LE1. However, the present disclosure is not limited thereto. For example, the third organic layer 191 may also be formed higher than the first light emitting elements LE1 to entirely cover the side surfaces (e.g., the outer peripheral surfaces) of the first light emitting elements LE1.

A transparent electrode TE (also referred to as a “connection electrode” or an “intermediate electrode”) may be disposed on a first light emitting element LE1. For example, the transparent electrode TE may be disposed on at least one first light emitting element LE1 disposed in each subpixel SPX.

In one or more embodiments, a portion of the transparent electrode TE may be disposed on the third organic layer 191. For example, the transparent electrode TE may have a larger size than the first light emitting element LE1 in a plan view and may extend around the first light emitting element LE1 while completely covering the upper surface of the first light emitting element LE1.

The transparent electrode TE may be disposed or included in each subpixel SPX to connect the first light emitting element LE1 and the second light emitting element LE2 of the subpixel SPX. For example, the transparent electrode TE may be a contact electrode for ohmic contact between the first light emitting element LE1 and the second light emitting element LE2. The transparent electrode TE may be individually formed or patterned in an emission area of each subpixel SPX.

In one or more embodiments, the transparent electrode TE may be regarded as an element included in the second light emitting element LE2 or may be regarded as an element separate from the second light emitting element LE2. For example, the transparent electrode TE may form the second light emitting element LE2 together with the organic layer OL of the second light emitting element LE2 and/or the common electrode CE on the organic layer OL. For example, the transparent electrode TE may function as an anode of the second light emitting element LE2.

In one or more embodiments, the transparent electrode TE may be substantially transparent. For example, the transparent electrode TE may be made of a transparent conductive material (TCO) that can transmit light, such as indium tin oxide (ITO) and/or indium zinc oxide (IZO). Accordingly, light emitted from the first light emitting element LE1 can transmit through the transparent electrode TE.

In one or more embodiments, the transparent electrode TE may be disposed on the upper surface of the first light emitting element LE1 including the textured pattern PTN and may include an optical pattern having a shape corresponding to the textured pattern PTN of the first light emitting element LE1 (e.g., an optical pattern formed on the transparent electrode TE to have curves or irregularities according to the textured pattern PTN of the first light emitting element LE1). For example, the transparent electrode TE may have an overall uniform thickness and may be formed as a thin layer with a surface profile corresponding to a surface shape of an element located underneath it.

The curves or irregularities formed on the transparent electrode TE may function as an optical pattern that improves light output efficiency together with the textured pattern PTN of the first light emitting element LE1. For example, the curves or irregularities formed on the transparent electrode TE may scatter light emitted from the first light emitting element LE1 and/or the second light emitting element LE2 together with the textured pattern PTN of the first light emitting element LE1, thereby increasing the amount of light emitted from each subpixel SPX or the light output rate of each subpixel SPX.

In each subpixel SPX, the organic layer OL of the second light emitting element LE2 may be disposed on the transparent electrode TE. The organic layer OL may include an organic light emitting layer of the second light emitting element LE2. For example, the organic layer OL of the first subpixel SPX1 may include a first organic light emitting layer OL1 that emits light of the first color, and the organic layer OL of the second subpixel SPX2 may include a second organic light emitting layer OL2 that emits light of the second color. In addition, the organic layer OL of the third subpixel SPX3 may include a third organic light emitting layer OL3 that emits light of the third color. In one or more embodiments, the first organic light emitting layer OL1, the second organic light emitting layer OL2, and the third organic light emitting layer OL3 may be, but are not limited to, a red organic light emitting layer that emits red light, a green organic light emitting layer that emits green light, and a blue organic light emitting layer that emits blue light, respectively.

In one or more embodiments, the organic layer OL may further include at least one intermediate layer. For example, the organic layer OL may further include a hole injection layer, a hole transport layer, and/or an electron transport layer that overlap the organic light emitting layer disposed in each subpixel SPX. For example, the organic layer OL disposed in the first subpixel SPX1 may be the first organic light emitting layer OL1 or may be a multilayer including the first organic light emitting layer OL1 and at least one intermediate layer. Similarly, the organic layer OL disposed in the second subpixel SPX2 may be the second organic light emitting layer OL2 or may be a multilayer including the second organic light emitting layer OL2 and at least one intermediate layer. The organic layer OL disposed in the third subpixel SPX3 may be the third organic light emitting layer OL3 or may be a multilayer including the third organic light emitting layer OL3 and at least one intermediate layer.

The organic layer OL may be surrounded by the light blocking layer BM, etc. The light blocking layer BM may be disposed on the third organic layer 191 to separate the emission areas of the subpixels SPX. For example, the light blocking layer BM may be disposed between the emission areas of the subpixels SPX and/or around the emission areas. The light blocking layer BM may surround the second light emitting elements LE2 (or the organic layers OL of the second light emitting elements LE2) of the subpixels SPX. The light blocking layer BM can prevent or reduce light leakage and resultant color mixing between the subpixels SPX.

In one or more embodiments, the second light emitting element LE2 may be formed to a size that allows it to fully utilize the emission area of each subpixel SPX. For example, the transparent electrode TE may have a larger size than the first light emitting element LE1 in a plan view and completely cover the upper surface of the first light emitting element LE1, and the organic layer OL of the second light emitting element LE2 may fill the emission area of each subpixel SPX surrounded by the light blocking layer BM.

In one or more embodiments, heights of the organic layers OL of the second light emitting elements LE2 and the light blocking layer BM may be substantially equal or similar to each other. However, the preset disclosure is not limited thereto. For example, the shapes or heights of the organic layers OL of the second light emitting elements LE2 and the light blocking layer BM may vary according to the formation order or process method of the organic layers OL of the second light emitting elements LE2 and the light blocking layer BM.

The light blocking layer BM may include a light blocking material and may be composed of a single layer or multiple layers. For example, the light blocking layer BM may be composed of a single layer as illustrated in FIG. 11 or may be composed of multiple layers including a first light blocking layer BM1 and a second light blocking layer BM2 as illustrated in FIG. 6.

The light blocking layer BM may include vertical side surfaces as illustrated in FIG. 11 or may include inclined side surfaces as in the embodiment of FIG. 6. The light blocking layer BM may also have other shapes. For example, the shape, height, and/or structure of the light blocking layer BM may vary according to embodiments.

In one or more embodiments, the display panel 100 may further include a reflective layer RF disposed on the light blocking layer BM. For example, the reflective layer RF and a third capping layer CAP3 may be sequentially disposed on a second capping layer CAP2 covering the light blocking layer BM.

The reflective layer RF may cover at least the side surfaces of the light blocking layer BM. For example, the reflective layer RF may cover the side surfaces of the light blocking layer BM and expose an upper surface of the light blocking layer BM as illustrated in FIG. 11 and FIG. 12 or may cover the side and upper surfaces of the light blocking layer BM as illustrated in FIG. 6. In addition, the position and/or shape of the reflective layer RF may vary according to embodiments. The reflective layer RF may increase the amount of light emitted toward the top of the subpixels SPX (e.g., in the third direction DR3 or in a forward direction of the display panel 100 including a viewing angle range) and improve the light efficiency of the subpixels SPX.

The common electrode CE may be disposed on the organic layer OL of each subpixel SPX. In one or more embodiments, the common electrode CE may function as a cathode of each second light emitting element LE2. In one or more embodiments, the common electrode CE may be entirely disposed on the organic layers OL of the second light emitting elements LE2 disposed in the subpixels SPX and the light blocking layer BM around the organic layers OL. For example, the common electrode CE may be formed in the entire display area DA.

The common electrode CE may be substantially transparent. For example, the common electrode CE may be made of a transparent conductive material as described in the embodiment of FIG. 6.

In one or more embodiments, the common electrode CE may be regarded as an element included in each second light emitting element LE2 or may be regarded as an element separate from each second light emitting element LE2. For example, the common electrode CE may form each second light emitting element LE2 together with the organic layer OL and/or the transparent electrode TE of the second light emitting element LE2.

An encapsulation layer TFE may be disposed on the common electrode CE. In one or more embodiments, the encapsulation layer TFE may be disposed on the light emitting element layer including the light emitting elements LE of the subpixels SPX. The encapsulation layer TFE may cover the light emitting element layer and extend to a non-display area (e.g., the non-display area NDA of FIGS. 1 and 2) to contact a thin-film transistor layer TFTL. In one or more embodiments, the encapsulation layer TFE may include a first encapsulation layer TFE1, a second encapsulation layer TFE2, and a third encapsulation layer TFE3 sequentially disposed on the light emitting element layer (or the common electrode CE). The first encapsulation layer TFE1 and the third encapsulation layer TFE3 may include an inorganic material. The second encapsulation layer TFE2 may include an organic material and may be encapsulated by the first encapsulation layer TFE1 and the third encapsulation layer TFE3. The encapsulation layer TFE may block the penetration of oxygen and/or moisture into the light emitting element layer and alleviate electrical and/or physical shock to the thin-film transistor layer TFTL and the light emitting element layer.

Color filters CF1 through CF3 and a sixth organic layer 194 may be disposed on the encapsulation layer TFE. Although the color filters CF1 through CF3 have different thicknesses in FIG. 11, the present disclosure is not limited thereto. For example, the color filters CF1 through CF3 may also be formed to have substantially the same or similar thickness.

In one or more embodiments, the color filters CF1 through CF3 may be disposed on the light emitting elements LE of the subpixels SPX to selectively transmit light of a specific color or wavelength band emitted from the light emitting elements LE of each of the subpixels SPX. For example, a first color filter CF1 may be disposed on the first light emitting element LE1A of the first color and the second light emitting element LE2A of the first color of the first subpixel SPX1 to selectively transmit light of the first color emitted from the light emitting elements LE of the first subpixel SPX1. Similarly, a second color filter CF2 may be disposed on the first light emitting element LE1B of the second color and the second light emitting element LE2B of the second color of the second subpixel SPX2 to selectively transmit light of the second color emitted from the light emitting elements LE of the second subpixel SPX2, and a third color filter CF3 may be disposed on the first light emitting element LE1C of the third color and the second light emitting element LE2C of the third color of the third subpixel SPX3 to selectively transmit light of the third color emitted from the light emitting elements LE of the third subpixel SPX3. Accordingly, even if the subpixels SPX include different types of light emitting elements LE (e.g., the first light emitting element LE1 and the second light emitting element LE2 of each subpixel SPX), it is possible to appropriately and/or easily control the colors or wavelengths of light emitted from the subpixels SPX and possible to appropriately secure the color purity of light emitted from each subpixel SPX.

FIG. 13 is a cross-sectional view illustrating an example of a cross section of a display panel 100 corresponding to the line I2-I2′ of FIG. 10. FIG. 13 shows a cross section of the display panel 100 in which each subpixel SPX includes a first light emitting element LE1 and a second light emitting element LE2 as in the embodiments of FIGS. 8 through 10. In addition, FIG. 13 shows an embodiment different from the embodiment of FIG. 11 in relation to a light emitting element layer including light emitting elements LE.

Referring to FIG. 13, the display panel 100 may include an organic layer 210 disposed on pixel electrodes PXE, and first light emitting elements LE1 may be disposed on the organic layer 210. The first light emitting elements LE1 may not include the bonding electrodes BDE illustrated in FIG. 11 and may be respectively connected to the pixel electrodes PXE by connection electrodes BE.

For example, each of the first light emitting elements LE1 may have a structure or shape according to the embodiment of FIG. 7 and may not include a bonding electrode BDE illustrated in FIGS. 11 and 12. In addition, the first light emitting elements LE1 may be respectively connected to the pixel electrodes PXE through the connection electrodes BE as in the embodiment of FIG. 6. In one or more embodiments, each of the first light emitting elements LE1 may include a textured pattern PTN at (e.g., formed on) its upper surface as in the embodiment of FIGS. 11 and 12.

In one or more embodiments, the display panel 100 may further include a fourth organic layer 192 disposed on a third organic layer 191, and a light blocking layer BM and transparent electrodes TE may be disposed on the fourth organic layer 192. Alternatively, the display panel 100 may not include the fourth organic layer 192 as in the embodiment of FIGS. 11 and 12, and the light blocking layer BM and the transparent electrodes TE may be disposed on the third organic layer 191.

According to the embodiments of FIGS. 8 through 13, each of the subpixels SPX may include a plurality of light emitting elements LE including a first light emitting element LE1 and a second light emitting element LE2. Accordingly, the light efficiency of the subpixels SPX according to a driving current Ids (e.g., a driving current of a magnitude corresponding to a data voltage) can be improved.

For example, a subpixel SPX that does not include the second light emitting element LE2 may generate light corresponding to the driving current Ids by using at least one first light emitting element LE1. In one or more embodiments, the first light emitting element LE1 may be a micro-light emitting diode. Because the micro-light emitting diode is made of an inorganic material, it has better deterioration characteristics and a longer life than an organic light emitting diode. However, because the micro-light emitting diode has a relatively large surface area to volume ratio, a utilization rate of the driving current Ids may be reduced due to non-emission recombination that occurs on the surface. If a higher driving current Ids is supplied to the subpixels SPX to obtain a target luminance corresponding to a data voltage, the power consumption of the display device 10 may increase.

On the other hand, when each of the subpixels SPX includes the second light emitting element LE2 in addition to at least one first light emitting element LE1 as in the embodiments, the second light emitting element LE2 may generate additional light in response to the same driving current Ids. For example, when each of the subpixels SPX includes the first light emitting element LE1 and the second light emitting element LE2 connected to each other in series, both the first light emitting element LE1 and the second light emitting element LE2 may generate light in response to the same driving current Ids. Because light is emitted from the second light emitting element LE2 in addition to light emitted from the first light emitting element LE1 in response to the driving current Ids, the amount of light emitted from each subpixel SPX may increase. For example, the light emitting elements LE of each subpixel SPX may be made to emit light by utilizing the driving current Ids supplied to the subpixel SPX more efficiently. Accordingly, each subpixel SPX can emit light with higher luminance in response to the same driving current Ids.

As the amount of light generated and/or emitted from the subpixels SPX in response to the driving current Ids increases, the light efficiency of the subpixels SPX and a pixel PX including the subpixels SPX may be improved. In addition, as the light efficiency of the subpixels SPX is improved, the power consumption of the display device 10 may be reduced. For example, as the driving current utilization rate of the subpixels SPX increases, the magnitude of the driving current Ids that may be supplied to each of the subpixels SPX to express a target luminance (or gray level) may decrease. Accordingly, the power consumption of the display device 10 can be reduced or optimized.

In one or more embodiments, a data voltage and/or a driving current Ids corresponding to the data voltage may be adjusted or optimized according to the operating characteristics of the first light emitting element LE1 (e.g., the driving voltage range of the first light emitting element LE1). Accordingly, the first light emitting element LE1 can be driven appropriately or efficiently. In addition, as the driving current Ids also flows through the second light emitting element LE2, the second light emitting element LE2 may emit light to assist the amount of light generated and/or emitted from a subpixel SPX. However, the present disclosure is not limited thereto. For example, the data voltage or the driving current Ids may also be appropriately adjusted or changed in consideration of the driving voltage range of the second light emitting element LE2 or the overall light efficiency of the subpixel SPX.

In one or more embodiments, the subpixels SPX may include light emitting elements LE that emit light of colors corresponding to their emission colors. In addition, color filters CF1 through CF3 corresponding to the emission colors of the subpixels SPX may be disposed on the light emitting elements LE. Accordingly, it is possible to appropriately control and/or improve the colors (e.g., color purity) of light emitted from the subpixels SPX and/or the light output efficiency of the subpixels SPX.

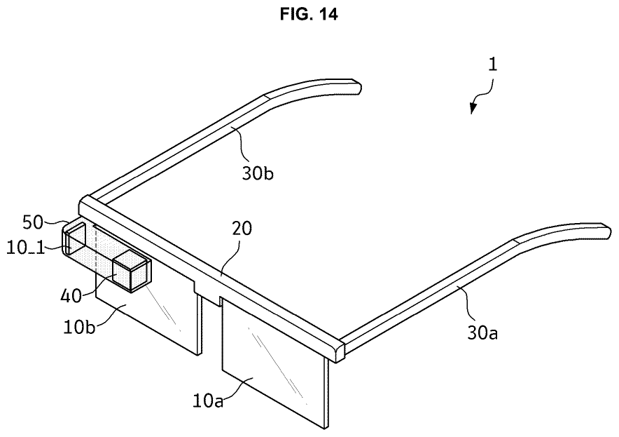

FIG. 14 is an example view of a virtual reality (VR) device including a display device according to one or more embodiments. FIG. 14 illustrates a VR device 1 to which a display device 10_1 according to an embodiment has been applied.

Referring to FIG. 14, the VR device 1 according to one or more embodiments may be a device in the form of glasses. The VR device 1 according to the embodiment may include the display device 10_1, a left lens 10a, a right lens 10b, a support frame 20, eyeglass frame legs 30a and 30b, a reflective member 40, and a display device housing 50.

In FIG. 14, the VR device 1 including the eyeglass frame legs 30a and 30b is illustrated as an example. However, the VR device 1 according to the embodiment may also be applied to a head mounted display including a head mounted band, which can be worn on the head, instead of the eyeglass frame legs 30a and 30b. That is, the VR device 1 according to the embodiment is not limited to the one illustrated in FIG. 14 and can be applied in various forms to various other electronic devices.

The display device housing 50 may include the display device 10_1 and the reflective member 40. An image displayed on the display device 10_1 may be reflected by the reflective member 40 and provided to a user's right eye through the right lens 10b. Accordingly, the user may view a VR image displayed on the display device 10_1 through the right eye.

Although the display device housing 50 is disposed at a right end of the support frame 20 in FIG. 14, the present disclosure is not limited thereto. For example, the display device housing 50 may also be disposed at a left end of the support frame 20. In this case, an image displayed on the display device 10_1 may be reflected by the reflective member 40 and provided to the user's left eye through the left lens 10a. Accordingly, the user may view a VR image displayed on the display device 10_1 through the left eye. Alternatively, the display device housing 50 may be disposed at both the right end and the left end of the support frame 20. In this case, the user may view a VR image displayed on the display device 10_1 through both the left eye and the right eye.

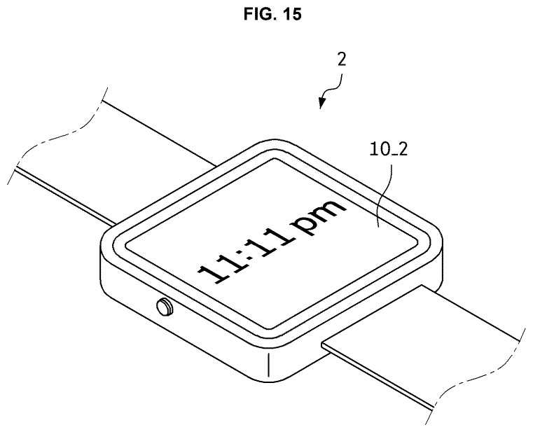

FIG. 15 is an example view of a smart watch including a display device according to one or more embodiments.

Referring to FIG. 15, a display device 10_2 according to one or more embodiments may be applied to a smart watch 2 which is one of smart devices.

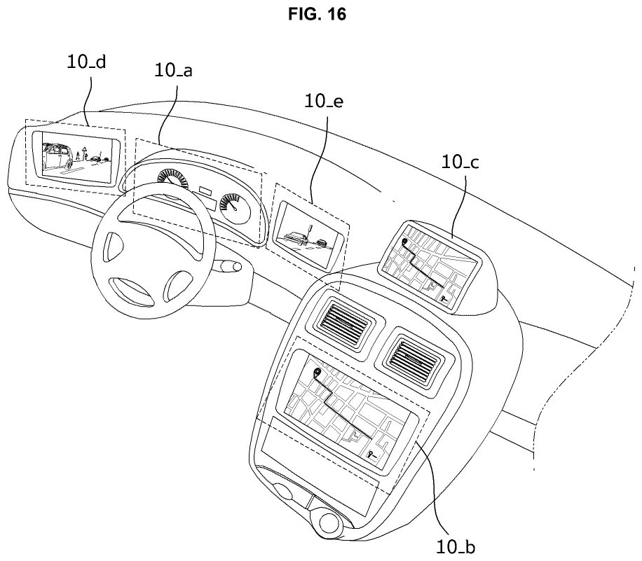

FIG. 16 is an example view illustrating a vehicle instrument cluster and center fascia including display devices according to one or more embodiments. FIG. 16 illustrates a vehicle to which display devices 10_a through 10_e according to one or more embodiments have been applied.

Referring to FIG. 16, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

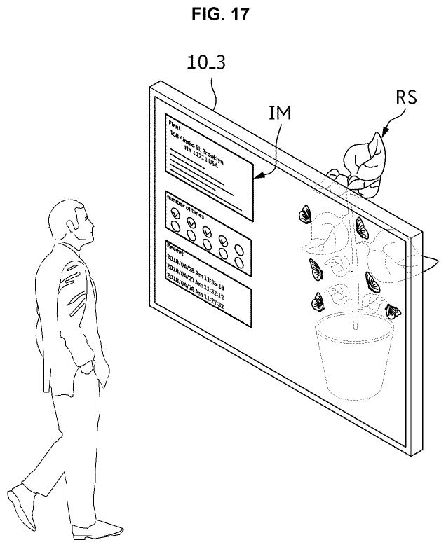

FIG. 17 is an example view of a transparent display device including a display device according to one or more embodiments.

Referring to FIG. 17, a display device 10_3 according to one or more embodiments may be applied to a transparent display device. The transparent display device may transmit light while displaying an image IM. Therefore, a user located in front of the transparent display device cannot only view the image IM displayed on the display device 10_3 but also view an object RS or the background located behind the transparent display device. When the display device 10_3 is applied to the transparent display device, a substrate SUB of the display device 10_3 may include a light transmitting portion that can transmit light or may be made of a material that can transmit light.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising a first subpixel in a display area, wherein the first subpixel comprises:
a first pixel electrode on a substrate;
a first light emitting element of a first color on the first pixel electrode and comprising a first inorganic light emitting layer configured to emit light of the first color; and
a second light emitting element of the first color on the first light emitting element of the first color and comprising a first organic light emitting layer configured to emit light of the first color.

2. The display device of claim 1, wherein the first subpixel further comprises a transparent electrode on the first light emitting element of the first color and connecting the first light emitting element of the first color and the second light emitting element of the first color.

3. The display device of claim 2, wherein the transparent electrode has a larger size than the first light emitting element of the first color in a plan view and completely covers an upper surface of the first light emitting element of the first color.

4. The display device of claim 3, further comprising a light blocking layer around an emission area where the first pixel electrode, the first light emitting element of the first color, and the second light emitting element of the first color are located, wherein the first organic light emitting layer is on the transparent electrode and fills the emission area.

5. The display device of claim 2, further comprising a common electrode on the first organic light emitting layer, wherein the first light emitting element of the first color and the second light emitting element of the first color are connected in series between the first pixel electrode and the common electrode.

6. The display device of claim 2, wherein the first light emitting element of the first color comprises a textured pattern at an upper surface of the first light emitting element of the first color.

7. The display device of claim 6, wherein the transparent electrode on the first light emitting element comprises an optical pattern having a shape corresponding to the textured pattern.

8. The display device of claim 1, wherein the first light emitting element of the first color is a micro-light emitting diode.

9. The display device of claim 1, further comprising a first color filter on the first light emitting element of the first color and the second light emitting element of the first color and configured to selectively transmit light of the first color.

10. The display device of claim 1, further comprising a second subpixel in the display area, wherein the second subpixel comprises:
a second pixel electrode on the substrate;
a first light emitting element of a second color on the second pixel electrode and comprising a second inorganic light emitting layer configured to emit light of the second color; and
a second light emitting element of the second color on the first light emitting element of the second color and comprising a second organic light emitting layer configured to emit light of the second color.

11. The display device of claim 10, further comprising a common electrode on the second organic light emitting layer, wherein the first light emitting element of the second color and the second light emitting element of the second color are connected in series between the second pixel electrode and the common electrode.

12. The display device of claim 10, further comprising a second color filter on the first light emitting element of the second color and the second light emitting element of the second color and configured to selectively transmit light of the second color.

13. The display device of claim 10, further comprising a third subpixel in the display area, wherein the third subpixel comprises:
a third pixel electrode on the substrate;
a first light emitting element of a third color on the third pixel electrode and comprising a third inorganic light emitting layer configured to emit light of the third color; and
a second light emitting element of the third color on the first light emitting element of the third color and comprising a third organic light emitting layer configured to emit light of the third color.

14. The display device of claim 13, further comprising a common electrode on the third organic light emitting layer, wherein the first light emitting element of the third color and the second light emitting element of the third color are connected in series between the third pixel electrode and the common electrode.

15. The display device of claim 13, further comprising a third color filter on the first light emitting element of the third color and the second light emitting element of the third color and configured to selectively transmit light of the third color.

16. The display device of claim 13, wherein the light of the first color is red light, the light of the second color is green light, and the light of the third color is blue light.

17. A display device comprising a pixel in a display area, wherein the pixel comprises:
a first subpixel comprising a first pixel electrode, a first light emitting element of a first color on the first pixel electrode, and a second light emitting element of the first color on the first light emitting element of the first color;
a second subpixel comprising a second pixel electrode, a first light emitting element of a second color on the second pixel electrode, and a second light emitting element of the second color on the first light emitting element of the second color; and
a third subpixel comprising a third pixel electrode, a first light emitting element of a third color on the third pixel electrode, and a second light emitting element of the third color on the first light emitting element of the third color.

18. The display device of claim 17, wherein each of the first light emitting element of the first color, the first light emitting element of the second color, and the first light emitting element of the third color comprises an inorganic light emitting layer.

19. The display device of claim 17, wherein each of the second light emitting element of the first color, the second light emitting element of the second color, and the second light emitting element of the third color comprises an organic light emitting layer.

20. The display device of claim 17, further comprising:
a first color filter on the first light emitting element of the first color and the second light emitting element of the first color and configured to selectively transmit light of the first color;
a second color filter on the first light emitting element of the second color and the second light emitting element of the second color and configured to selectively transmit light of the second color; and
a third color filter on the first light emitting element of the third color and the second light emitting element of the third color and configured to selectively transmit light of the third color.

21. An electronic device for providing an image, comprising:
a display device comprising a first subpixel in a display area, wherein the first subpixel comprises:
a first pixel electrode on a substrate;
a first light emitting element of a first color on the first pixel electrode and comprising a first inorganic light emitting layer configured to emit light of the first color; and
a second light emitting element of the first color on the first light emitting element of the first color and comprising a first organic light emitting layer configured to emit light of the first color.
